(19) United States
(12) Patent Application Publication
(10) Pub. No.: US 2022/0128222 A1
(43) Pub. Date: Apr. 28, 2022

(54) OPTICAL ELEMENT FOR IMPROVING BEAM QUALITY AND LIGHT COUPLING EFFICIENCY

(71) Applicants: Amir Lotfi, Redondo Beach, CA (US); David Kessler, New York, NY (US)

(72) Inventors: Amir Lotfi, Redondo Beach, CA (US); David Kessler, New York, NY (US)

(73) Assignee: Ver Lighting LLC, Carson, CA (US)

(21) Appl. No.: 17/551,073

(22) Filed: Dec. 14, 2021

Related U.S. Application Data
(63) Continuation of application No. PCT/US2020/039728, filed on Jun. 26, 2020.
(60) Provisional application No. 62/867,004, filed on Jun. 26, 2019.

(51) Int. Cl. F21V 7/00; F21V 5/04; G02B 19/00; H01L 33/60

(52) U.S. Cl. CPC F21V 7/0091; F21V 5/04; F21Y 2105/18; H01L 33/60; G02B 19/0061

(57) ABSTRACT

A hybrid optic includes a folded optical element with an outer reflective surface, an output surface, and a hollow core comprising a sidewall, a core output surface, and a core input opening through which light emitted by a light source enters the hollow core. A reflector element, coupled to the folded optical element, receives light from the light source, reflects a portion of the light into the hollow core and directly transmits the remaining portion of the light into the hollow core. To reduce the appearance of non-uniformities in the output light, the reflector element is diffuse and white, portions of the folded optical element are diffusely reflective, and/or a glare control diffuser is disposed on the output surface to disperse light transmitted through the core output surface of the hollow core. In this manner, the light coupling efficiency of the hybrid optic is enhanced without producing structured light.

### CROSS-REFERENCE TO RELATED APPLICATION

This application is a bypass continuation of International Patent Application No. PCT/US2020/039728, filed on Jun. 26, 2020, titled “Optical Element for Improving Beam Quality and Light Coupling Efficiency,” which application claims priority to U.S. Provisional Application No. 62/867,004, filed on Jun. 26, 2019, entitled “A Hybrid Optic for Improving Beam Quality and Glare Reduction”, both of which applications are incorporated herein by reference in their entirety.

### BACKGROUND

Conventional lighting systems (also referred to as lighting fixtures or luminaires), such as downlights, spotlights, and surface lights, often include an optical element to receive and redirect light emitted by a light source. Generally, the performance of the optical element may be evaluated based on a light coupling efficiency, which is defined as the ratio of (1) the luminous flux radiated out of the optical element and (2) the luminous flux input into the optical element. For conventional optical elements (e.g., a total internal reflection (TIR) collimator), the light coupling efficiency typically increases with the overall size of the optical element. A larger optical element, however, results in a larger, heavier, and more expensive lighting system. Furthermore, lighting systems that incorporate a high efficiency optical element are typically unable to accommodate environments with limited ceiling and/or wall space (e.g., a multi-family housing, a commercial office).

One approach to improve upon conventional optical elements with size and performance constraints is to utilize a folded optical element in a lighting system. For example, FIG. 1A shows a cross-sectional view of a conventional folded optical element 100a coupled to a light source 104. As shown, the folded optical element 100a includes an input surface 108 to receive light from the light source 104, an output surface 114 from which the light exits the folded optic element 100a, and a reflective outer surface 110 to reflect a portion of the light propagating within the folded optic element 100a.

The light emitted by the light source 104 follows several paths through the folded optical element 100a depending on the emission angle, which is defined with respect to an axis parallel to an optical axis 101 of the folded optical element 100a and a position along the light source 104. For reference, the light source 104 is centered to the optical axis 101. In one example, light that is emitted at a small emission angle (i.e., an angle that is less than the critical angle for TIR at the output surface 114), such as the light ray 103, radiates directly out of the folded optical element 100a via transmission through the output surface 114.

In another example, light that is emitted at a large emission angle (i.e., an angle that is greater than or equal to the critical angle for TIR at the output surface 114), such as the light ray 106, radiates indirectly out of the folded optical element 100a. As shown, the light ray 106 is first reflected by the output surface 114 via TIR and then reflected again by the reflective outer surface 110 such that the light ray 106 is incident on the output surface 114 at a small incidence angle (i.e., below the critical angle for TIR). The light ray 106 then exits the folded optical element 100a via transmission through the output surface 114.

The multiple reflections provided by the output surface 114 and the reflective outer surface 110 effectively folds the optical path of the light ray 106. In this manner, the folded optical element 100a provides a longer optical path to orient light emitted at larger emission angles along a desired direction (e.g., the light is collimated) without increasing the size of the folded optical element 100a. In fact, a typical folded optical element can have a thickness that is nearly half that of a conventional TIR collimator.

FIG. 1B shows another conventional folded optical element 100b that includes a hollow core 102 (also referred to as a “funnel”). The hollow core 102 provides additional surfaces better control over the spatial and angular intensity distribution of the light exiting the folded optical element 100b compared to the folded optical element 100a. As shown, the hollow core 102 defines a cavity 118 to receive the light from the light source 104. A portion of the light, such as light ray 106, is refracted by the sidewall 112 of the hollow core 102 before being reflected by the output surface 114 and the reflective outer surface 110 as before. Another portion of the light, such as light ray 103, is refracted by a core output surface 107 before exiting the folded optical element 100b via transmission through the output surface 114.

### SUMMARY

The Inventors have recognized and appreciated that folded optical elements provide a lighter, more compact optic compared to conventional optical elements while providing similar capabilities in terms of modifying the spatial and angular distribution of light (e.g., the folded optical element may provide collimated light with a divergence angle similar to previous TIR collimators). However, the Inventors have also recognized that conventional folded optical elements typically suffer from lower light coupling efficiencies compared to conventional optical elements, thus reducing the luminosity of the lighting system.

The lower light coupling efficiency may be attributed, at least in part, to conventional folded optical elements being unable to redirect light emitted at large emission angles. For example, FIGS. 1A and 1B show that light emitted at a sufficiently large angle, such as the light ray 199, does not exit through the output surface 114, but is instead lost through the base of the folded optical elements 100a and 100b. Due to optical losses, the folded optical elements 100a and 100b typically exhibit a light coupling efficiency of η=60-80%. For comparison, conventional TIR collimators typically exhibit a light coupling efficiency of η=80%-95%.

The Inventors have also recognized the multiple pathways through which light is directed through a folded optical element may give rise to non-uniformities in the spatial and/or angular distribution of the light exiting the folded optical element. Output light with observable non-uniformities (also referred to as “structured light”) is generally considered to be aesthetically undesirable. The non-uniformities may include localized spots and/or rings of high or low intensity. The light may also exhibit undesirable grazing and/or scalloping when illuminating a surface of an environment (e.g., a wall). In some cases, the light may have a double scallop or a triple scallop where the spatial distribution of the light on the surface includes at least two regions with distinctly different and observable light intensities separated by a gap (e.g., zero light intensity) or a sudden transition (e.g., an observable boundary in the light distribution). The light may also exhibit undesirable glare caused by the light having high intensities concentrated along certain directions, which may lead to discomfort when a user looks at the light along these directions.

The observation of these various non-uniformities may each contribute to the overall reduction in beam quality of the light provided by the lighting system. Typically, a folded optical element supporting more optical paths exhibits more non-uniformities in its output light. For this reason, conventional folded optical elements often limit the number of optical paths available for light to propagate in the folded optical element in order to provide a higher beam quality (i.e., fewer observable non-uniformities) at the expense of a lower light coupling efficiency. For example, in some previous folded optical elements, an opaque reflector was disposed on the output surface to block light that may otherwise radiate directly out of the folded optical element (e.g., the light ray 103 in the folded optical element 100a). Instead, the light is redirected back towards the light source and subsequently lost within the lighting system. Examples of folded optical elements with opaque reflectors may be found in U.S. Pat. No. 8,757,846.

The present disclosure is thus directed towards various inventive apparatuses and methods for increasing the light coupling efficiency and the beam quality of a lighting system (e.g., a downlight, a spotlight, a surface light) while maintaining a compact size. In some implementations, a hybrid optic (also referred to as an “optical element”) may include a folded optical element that guides and outputs light emitted by a light source in the lighting system with a desired intensity and/or angular distribution. The hybrid optic may also include a reflector element positioned at the base of the folded optical element to couple light emitted at large emission angles into the folded optical element, thus increasing the light coupling efficiency. In general, the shape and dimensions of the hybrid optic may be tailored to accommodate lighting systems with constrained dimensions and different sized light sources in order to provide output light with a desired divergence angle (also referred to as the “beam angle”) and/or spatial and angular intensity distribution.

In some implementations, the folded optical element of the hybrid optic may include a hollow core to receive light from a light source (e.g., a light emitting diode or LED), a reflective outer surface to reflect a portion of the light along a desired direction, and an output surface from which the light exits the folded optical element. The output surface may also reflect a portion of the light before the light exits the folded optical element. The hollow core may include a sidewall, a core output surface (also referred to as a “core output boundary”), and a core input opening defined by the sidewall for light to enter the hollow core. The reflector element of the hybrid optic may include a sidewall defining an input opening to receive light from the light source and an output opening for light to exit the reflector element and enter the folded optical element through the hollow core. The reflector element may thus reflect a portion of the light into the hollow core of the folded optical element and transmit the remaining portion of the light directly into the hollow core without reflection by the reflector element.

In some implementations, the hybrid optic may be configured to collimate the light from the light source. For instance, the hybrid optic may output light with a beam divergence angle less than about 12 degrees. The shape and dimensions of the hybrid optic may also vary depending on the size of the lighting system. For example, the output surface of the folded optical element may have a diameter that ranges between about 35 mm and about 110 mm. The overall thickness of the hybrid optic (i.e., the distance between the input opening of the reflector element and the output surface of the folded optical element) may be between about 8 mm and about 15 mm. In some implementations, the dimensions of the hybrid optic (and an optic holder) may be scaled for smaller and/or larger sized hybrid optics.

Unlike previous folded optical elements, the hybrid optic described herein may support numerous optical paths to increase the light coupling efficiency. The hybrid optic may also include several features to improve the beam quality (i.e., reduce the appearance of undesirable spots/rings, scalloping, and glare) without sacrificing the light coupling efficiency. In some implementations, the reflector element may have a reflective surface that is optically diffuse (e.g., white in appearance) to distribute light along the multiple optical paths more uniformly compared to a specular reflector.

In some implementations, the core output surface of the hollow core, surface(s) located between the output surface and the reflective outer surface (e.g., surfaces of a lip), and/or surface(s) located between the reflective outer surface and the core input opening (e.g., surface(s) of a base) may be textured. The textured surface(s) may reduce the appearance of non-uniformities in the light output caused by stray reflection and/or refraction of light towards portions of the folded optical element used only for support and/or connection with other components (e.g., the reflector element, an optic holder). In some implementations, the textured surface(s) may have a matte appearance. In some implementations, the textured surface(s) may diffusely reflector and/or transmit light within a diffusion angle that ranges between about 3 degrees and about 100 degrees. In some implementations, the textured surface(s) may be substantially reflective in order to prevent unwanted loss of stray light propagating in the folded optical element.

The hybrid optic may also include a glare control diffuser to reduce unwanted glare and scalloping of the light. The glare and scalloping may be caused, in part, by differences in the intensity of the light exiting the folded optical element through the core output surface and the light exiting the folded optical element after undergoing multiple reflections within the folded optical element. The glare control diffuser may include a plurality of prisms to disperse (i.e., diffusely transmit) light refracted by the core output surface in order to provide a smoother spatial and/or angular light distribution, thus reducing unwanted glare and scalloping. The glare control diffuser may be coupled to or integrated with the output surface of the folded optical element and located proximate to the core output surface.

Based on the above modifications (e.g., a diffuse reflector element, one or more textured surfaces on the folded optical element, a glare control diffuser), the hybrid optic provides a higher light coupling efficiency compared to conventional folded optical elements and light output with desired beam characteristics (e.g., beam shape, divergence angle) while improving the overall beam quality of the light output.

In one exemplary implementation, an optical element to redirect light emitted by a light source during operation of the light source includes a folded optical element with a hollow core, an output surface, and a reflective outer surface. The hollow core includes a sidewall surrounding a cavity and defining an opening through which the light enters the cavity where the sidewall refracts a first portion of the light and a core output surface joined to the sidewall to refract a second portion of the light. The output surface provides a surface from which the light exits the folded optical element where the output surface also reflects the first portion of the light before the first portion of the light exits the folded optical element. The optical element also includes a glare control diffuser disposed on the output surface proximate to the core output surface, to disperse the second portion of the light.

In another exemplary implementation, an optical element to redirect light emitted by a light source during operation of the light source includes a folded optical element with a hollow core, an output surface, and a reflective outer surface. The hollow core includes a sidewall surrounding a cavity and defining an opening (209) through which the light enters the cavity and a core output surface joined to the sidewall. Light exits the folded optical element through the output surface and the output surface also reflects at least a portion of the light before the portion of the light exits the folded optical element. In this implementation, at least one surface of the folded optical element is textured to at least one of diffusely reflect or diffusely transmit light incident on the at least one surface.

In another exemplary implementation, an optical element to redirect light emitted by a light source during operation of the light source includes a folded optical element with a hollow core, an output surface, and a reflective outer surface. The hollow core includes a sidewall surrounding a cavity and defining an opening through which the light enters the cavity and a core output surface joined to the sidewall. Light exits the folded optical element through the output surface and the output surface also reflects at least a portion of the light before the portion of the light exits the folded optical element. The optical element also includes a reflector element optically coupled to the opening of the hollow core and disposed outside the hollow core. Specifically, the reflector element includes a reflector sidewall defining a reflector input opening to receive the light from the light source and a reflector output opening for the received light to exit the reflector element. The reflector sidewall diffusely reflects at least a portion of the received light and the reflector element physically contacts the folded optical element.

It should be appreciated that all combinations of the foregoing concepts and additional concepts discussed in greater detail below (provided such concepts are not mutually inconsistent) are contemplated as being part of the inventive subject matter disclosed herein. In particular, all combinations of claimed subject matter appearing at the end of this disclosure are contemplated as being part of the inventive subject matter disclosed herein. It should also be appreciated that terminology explicitly employed herein that also may appear in any disclosure incorporated by reference should be accorded a meaning most consistent with the particular concepts disclosed herein.

### BRIEF DESCRIPTION OF THE DRAWINGS

The skilled artisan will understand that the drawings primarily are for illustrative purposes and are not intended to limit the scope of the inventive subject matter described herein. The drawings are not necessarily to scale; in some instances, various aspects of the inventive subject matter disclosed herein may be shown exaggerated or enlarged in the drawings to facilitate an understanding of different features. In the drawings, like reference characters generally refer to like features (e.g., functionally similar and/or structurally similar elements).

FIG. 1A shows a conventional folded optical element with no hollow core.

FIG. 1B shows a conventional folded optical element with a hollow core.

FIG. 2 shows a cross-sectional view of an exemplary hybrid optic.

FIG. 3A shows the aspheric profiles of the hollow core sidewall and the reflective outer surface of the hybrid optic of FIG. 2.

FIG. 3B shows a table of the various parameters that define the aspheric profiles of the hollow core sidewall and the reflective outer surface.

FIG. 4A shows a top perspective view of an exemplary folded optical element.

FIG. 4B shows a bottom perspective view of the folded optical element of FIG. 4A.

FIG. 4C shows a top view of the folded optical element of FIG. 4A.

FIG. 4D shows a front view of the folded optical element of FIG. 4A.

FIG. 4E shows a bottom view of the folded optical element of FIG. 4A.

FIG. 4F shows a cross-sectional view of the folded optical element corresponding to the cross-section A-A of FIG. 4E.

FIG. 4G shows a magnified view of the reflective outer surface of the folded optical element of FIG. 4A corresponding to the inset B of FIG. 4E.

FIG. 4H shows a table of parameters related to the prismatic structure of the reflective outer surface of FIG. 4G.

FIG. 4I shows a table of parameters related to various aspherical profiles of the reflective outer surface for various sized folded optical elements.

FIG. 5A shows a top perspective view of an exemplary reflector element.

FIG. 5B shows a bottom perspective view of the reflector element of FIG. 5A.

FIG. 5C shows a top view of the reflector element of FIG. 5A.

FIG. 5D shows a front view of the reflector element of FIG. 5A.

FIG. 5E shows a bottom view of the reflector element of FIG. 5A.

FIG. 5F shows a cross-sectional view of the reflector element corresponding to the cross-section A-A of FIG. 5E.

FIG. 6A shows an exploded front view of an exemplary hybrid optic that includes the folded optical element of FIG. 4A and the reflector element of FIG. 5A.

FIG. 6B shows a magnified view of the hybrid optic corresponding to the inset A of FIG. 6A.

FIG. 7 shows an image of an exemplary light source.

FIG. 8A shows a bottom perspective view of an exemplary hybrid optic with at least one textured surface.

FIG. 8B shows a bottom view of the hybrid optic of FIG. 8A.

FIG. 8C shows a top view of the hybrid optic of FIG. 8A

FIG. 8D shows an exploded bottom perspective view of the hybrid optic of FIG. 8A.

FIG. 8E shows an exploded top perspective view of the hybrid optic of FIG. 8A.

FIG. 8F shows a cross-sectional bottom perspective view of the hybrid optic corresponding to the plane A-A of FIG. 8B.

FIG. 9A shows a top perspective view of an exemplary optical assembly with a hybrid optic and an optic holder.

FIG. 9B shows a bottom perspective view of the optical assembly of FIG. 9A.

FIG. 9C shows a top view of the optical assembly of FIG. 9A.

FIG. 9D shows a bottom view of the optical assembly of FIG. 9A.

FIG. 9E shows a front view of the optical assembly of FIG. 9A.

FIG. 9F shows a right-side view of the optical assembly of FIG. 9A.

FIG. 9G shows a cross-sectional view of the optical assembly corresponding to the plane A-A of FIG. 9C.

FIG. 10A shows a top perspective view of the hybrid optic in the optical assembly of FIG. 9A with a folded optical element, a reflector element, and a glare control diffuser.

FIG. 10B shows a bottom perspective view of the hybrid optic of FIG. 10A.

FIG. 10C shows a top view of the hybrid optic of FIG. 10A.

FIG. 10D shows a bottom view of the hybrid optic of FIG. 10A.

FIG. 10E shows a front-side view of the hybrid optic of FIG. 10A.

FIG. 10F shows a cross-sectional view of the hybrid optic corresponding to the plane A-A of FIG. 10C.

FIG. 10G shows an exploded top perspective view of the hybrid optic of FIG. 10A.

FIG. 10H shows an exploded bottom perspective view of the hybrid optic of FIG. 10A.

FIG. 10I shows an exploded, cross-sectional view of the hybrid optic corresponding to the plane A-A of FIG. 10C.

FIG. 11A shows a magnified view of the glare control diffuser of FIG. 10A.

FIG. 11B shows an exemplary prism in the glare control diffuser.

FIG. 11C shows exemplary conical prisms for the glare control diffuser.

FIG. 11D shows a perspective view of the conical prisms of FIG. 11C.

FIG. 12A shows a top perspective view of the optic holder in the optical assembly of FIG. 9A.

FIG. 12B shows a bottom perspective view of the optic holder of FIG. 12A.

FIG. 12C shows a top view of the optic holder of FIG. 12A.

FIG. 12D shows a bottom view of the optic holder of FIG. 12A.

FIG. 12E shows a front view of the optic holder of FIG. 12A.

FIG. 12F shows a right-side view of the optic holder of FIG. 12A.

FIG. 13A shows a top perspective view of another optical assembly with a glare control diffuser attached to the folded optical element.

FIG. 13B shows a top perspective view of the glare control diffuser of FIG. 13A.

FIG. 13C shows a front view of the glare control diffuser of FIG. 13A.

FIG. 14A shows a top view of a simulation model of an exemplary hybrid optic.

FIG. 14B shows a bottom view of the simulation model of FIG. 14A.

FIG. 15A shows a ray race of a hybrid optic with a white deep trim without a filter and a glare control diffuser. The rays shown correspond to rays that intersect a side plane representing a wall.

FIG. 15B shows a magnified view of the ray trace of FIG. 15A.

FIG. 15C shows a ray trace of the hybrid optic of FIG. 15A where the rays shown correspond to rays that intersect a bottom plane located 150 mm below the hybrid optic.

FIG. 15D shows a magnified view of the ray trace of FIG. 15C.

FIG. 16A shows a ray trace of the hybrid optic with a glare control diffuser attached to the folded optical element and without a filter where the rays shown correspond to rays that intersect a side plane representing a wall.

FIG. 16B shows a magnified view of the ray trace of FIG. 16A.

FIG. 17A shows a ray trace of the hybrid optic with a glare control diffuser integrated into the folded optical element and without a filter where the rays shown correspond to rays that intersect a side plane representing a wall.

FIG. 17B shows a magnified view of the ray trace of FIG. 17A.

FIG. 17C shows a ray trace of the hybrid optic of FIG. 17A where the rays shown correspond to rays that intersect a bottom plane located 100 mm below the hybrid optic.

FIG. 17D shows a magnified view of the ray trace of FIG. 17C.

FIG. 18A shows an exemplary illumination pattern on a wall using a luminaire without a glare control diffuser.

FIG. 18B shows an exemplary illumination pattern on a wall using a luminaire with a glare control diffuser.

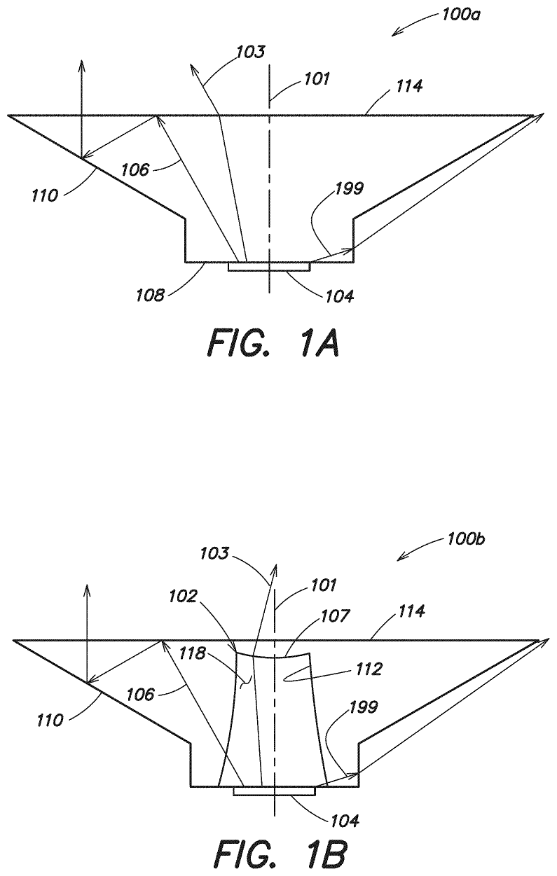

### DETAILED DESCRIPTION

Following below are more detailed descriptions of various concepts related to, and implementations of, a hybrid optic having a folded optical element and methods for redirecting light via the hybrid optic to increase the light coupling efficiency, beam quality (e.g., a smooth spatial and/or angular intensity profile, no dark spots, no bright spots, no scalloping), and the aesthetic appearance of a lighting system. It should be appreciated that various concepts introduced above and discussed in greater detail below may be implemented in multiple ways. Examples of specific implementations and applications are provided primarily for illustrative purposes so as to enable those skilled in the art to practice the implementations and alternatives apparent to those skilled in the art.

The figures and example implementations described below are not meant to limit the scope of the present implementations to a single embodiment. Other implementations are possible by way of interchange of some or all of the described or illustrated elements. Moreover, where certain elements of the disclosed example implementations may be partially or fully implemented using known components, in some instances only those portions of such known components that are necessary for an understanding of the present implementations are described, and detailed descriptions of other portions of such known components are omitted so as not to obscure the present implementations.

In the discussion below, various examples of inventive hybrid optics are provided, wherein a given example or set of examples showcases one or more particular features of a folded optical element, a reflector element, a glare control diffuser, and/or an optic holder. It should be appreciated that one or more features discussed in connection with a given example of a hybrid optic may be employed in other examples of hybrid optics according to the present disclosure, such that the various features disclosed herein may be readily combined in a given hybrid optic according to the present disclosure (provided that respective features are not mutually inconsistent).

A Hybrid Optic with a Reflector Element

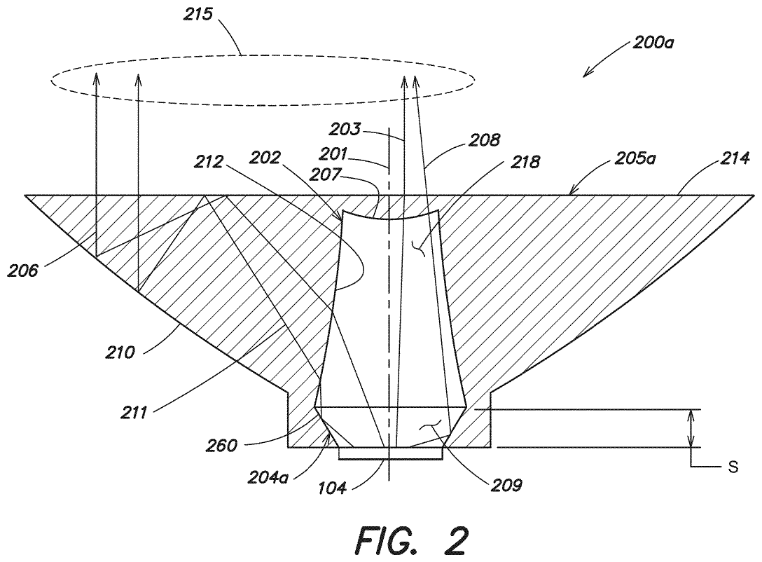

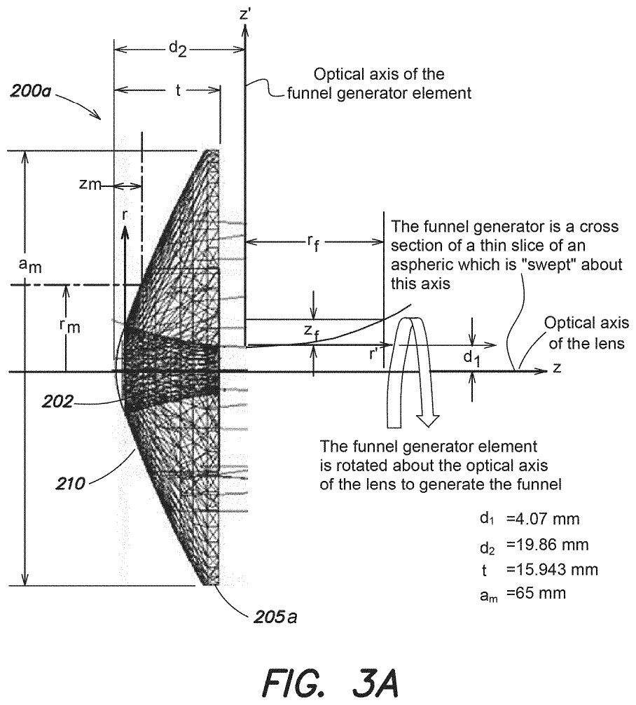

FIG. 2 shows an exemplary hybrid optic 200a according to one inventive implementation. Specifically, FIG. 2 shows a cross-section of the hybrid optic 200a, which is axisymmetric about an optical axis 201. As shown, the hybrid optic 200a includes a folded optical element 205a and a reflector element 204a joined to a base of the folded optical element 205a. A light source 104 is shown disposed below the reflector element 204a for reference in relation to the hybrid optic 200a. As shown, the folded optical element 205a may include a hollow core 202 to receive light, a reflective outer surface 210 to reflect a portion of the light, and an output surface 214 for light to exit the folded optical element 205a. The output surface 214 may also reflect a portion of the light before the light exits the folded optical element 205a. The hollow core 202 may include a sidewall 212 that defines a core input opening 209 and surrounds a cavity 218. A core output opening 207 may be joined to the sidewall 212. The reflector element 204a may include a reflective surface 260 to reflect a portion of the light entering the reflector element 204a from the light source 104.

At a particular position on the light source 104, light emitted at small emission angles (e.g., light ray 203) may radiate directly out of the hybrid optic 200a by being first refracted by the core output surface 207 and then refracted by the output surface 214. Light emitted at intermediate emission angles (e.g., light ray 206) may indirectly radiate out of the optic 200a. The light ray 206 is refracted by the sidewall 212, reflected at the output surface 214 via TIR, reflected at the reflective outer surface 210 (e.g., via TIR, via reflection from a specularly reflecting surface), and refracted by the output surface 214. Light emitted at large emission angles may be first reflected by the reflective surface 260 of the reflector element 204a and may either: (1) radiate directly out of the output surface 214 (e.g., light ray 208) similar to the light ray 203 emitted at small emission angles or (2) refracted by the sidewall 212 (e.g., light ray 211) and reflected several times similar to the light ray 206. In this manner, light emitted across a broad range of emission angles (e.g., 0 degrees to 90 degrees) at a particular position on the light source 104 may be substantially coupled to the hybrid optic 200a and outputted into an environment, thus increasing the light coupling efficiency.

The manner in which light emitted by the light source 104 couples out of the hybrid optic 200a depends on both the position on the light source 104 and the emission angle. For simplicity, light emitted by the light source 104 may instead be grouped together according to the particular surface the light rays intersect in the hybrid optic 200a regardless of the position on the light source 104 and/or the emission angle from which the light ray is emitted. Based on the various optical paths described above, a first light ray bundle (i.e., a collection of light rays) may be defined as light that directly radiates out of the hybrid optic 200a via transmission through the core output surface 207 and the output surface 214 (e.g., light rays 203 and 208). A second light ray bundle may be defined as light that indirectly radiates out of the hybrid optic 200a via refraction by the sidewall 212, reflection at the output surface 214 via TIR, reflection at the reflective outer surface 210, and transmission through the output surface 214 (e.g., light rays 206 and 211).

Accordingly, the hybrid optic 200a may be designed by considering the respective surfaces that reflect and/or refract the first and second light bundles described above. For instance, the curvature of the reflective surface 260, the core output surface 207, and the output surface 214 affects the coupling efficiency of the first light bundle. The curvature of the reflector surface 260, the sidewall 212, the output surface 214, and the reflective outer surface 210 affects the coupling efficiency of the second light bundle.

The curvature of each respective surface of the hybrid optic 200a may also depend on other desired output characteristics of the luminaire, such as the desired spatial and angular intensity distribution. For example, the intensity distribution may be represented by f(x), where x is either the position (e.g., a lateral position along the width of the output light beam) or the angle of the light coupled out of the hybrid optic 200a (e.g., the output angle as measured from the optical axis 201). A sufficiently smooth intensity distribution may be achieved if f(x) and the first derivative, df/dx(x), exhibit few, if any, discontinuities and the second derivative, d²f/dx²(x), exhibit few, if any, inflection points, such that the light appears to be non-structured (e.g., no rings, spots of higher or lower intensity) to the human eye.

Additional constraints may also be imposed on the hybrid optic 200a, which may affect the curvature and size of each respective surface of the hybrid optic 200a. For example, the design of the hybrid optic 200a may depend on the spatial and angular distribution of light rays emitted from the light source 104. For instance, it may be preferable in some implementations for the hybrid optic 200a to be relatively larger than the light source 104 such that the light rays emitted by the light source 104 do not substantially vary as a function of position. However, dimensional constraints may also be imposed where the hybrid optic 200a is limited to a particular size defined by the lighting system (e.g., the housing within which the hybrid optic 200a is located) and/or the amount of space available in a ceiling or a wall where the lighting system may be located. The design of the hybrid optic 200a may also be constrained by the materials used to form the hybrid optic 200a. In particular, the refractive index of the folded optical element 205a affects the critical angle for TIR at, for example, the output surface 214, which in turn, may affect the curvature and the resultant size of the hybrid optic 200a.

In some implementations, the output surface 214 may be substantially flat. However, it should be appreciated the output surface 214 in other implementations may be curved in order to provide another surface to tailor the spatial and/or angular distribution of light exiting the hybrid optic 200a. For example, the portion of the output surface 214 proximate to the core output surface 207 may be curved such that light from the first light bundle is refracted differently from the second light bundle.

In some implementations, the curvature of the reflective surface 260, the sidewall 212, the core output surface 207, the reflective outer surface 210, and/or the output surface 214 may be designed using free form surfaces, e.g., non-uniform rational basis splines (NURBS), which are surfaces that are not constrained by a particular mathematical form and may thus be tailored to a particular set of constraints and desired metrics (e.g., the light coupling efficiency, the spatial intensity distribution, and the angular intensity distribution). However, the determination of a free form surface may be time consuming and/or computationally expensive.

Therefore, in some implementations, constraints may be imposed on the mathematical form describing the curvature of the sidewall 212, the core output surface 207, the reflective surface 260, the reflective outer surface 210, and/or the output surface 214. For instance, the curves may be assumed to be a conical surface, which may include, but is not limited to spherical, paraboloidal, ellipsoidal, and hyperboidal surfaces. In some implementations, the curves may have an aspherical profile that, in part, includes, polynomial terms of varying even order of the form x², x⁴, x⁶, x⁸, and so on. With this approach, the time and computational cost to design the hybrid optic 200a may be substantially reduced by reducing the number of free parameters and/or possible solutions for each respective surface in the hybrid optic 200a to sufficiently meet the desired output characteristics and constraints described above as well as providing a smooth function where convergence in design refinement is readily more attainable.

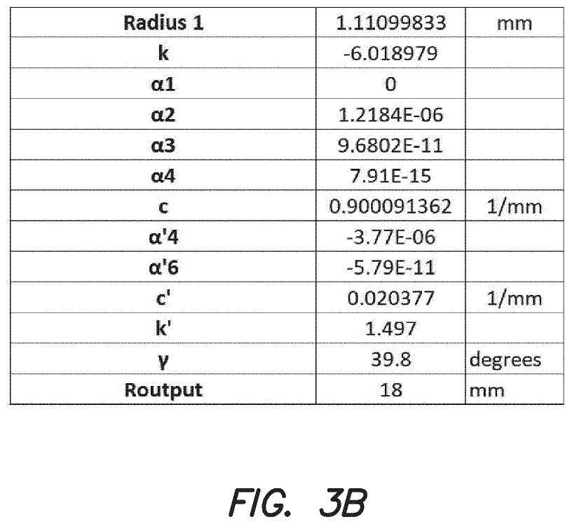

In one example, the hybrid optic 200a may be an axisymmetric structure formed by sweeping the cross-sectional profiles of the sidewall 212, the core output surface 207, the reflective surface 260, the reflective outer surface 210, and the output surface 214 about the optical axis 201 (also referred to as the z axis) of the hybrid optic 200a. The sidewall 212 and the reflective outer surface 210 may be constrained to have an aspheric profile. In particular, the sidewall 212 may be described by the following equation,

$${z}^{′} = \frac{{c}^{′} {r}^{′2}}{1 + \sqrt{1 - ( 1 + {k}^{′} ) {c}^{′2} {r}^{′2}}} + {α}_{4}^{′} {r}^{′4} + {α}_{6}^{′} {r}^{′6} \qquad ( 1 )$$

where c′ is the curvature, k′ is the conic order, and α′₄ and α′₆ are aspheric coefficients for each polynomial term. For Eq. (1), the variables r′ and z′ represent a radial distance along the radial axis and a sag along the optical axis of the aspheric profile of Eq. (1), respectively. The variables r′ and z′ form a second coordinate system specific to the aspherical profile of the sidewall 212, which may be orthogonal to the radial axis, r, and the optical axis, z, of the hybrid optic 200a as shown in FIG. 3A. The position of the origin of the second coordinate system in relation to r and z of the hybrid optic 200a may be translated to adjust the portion of the aspheric profile forming the sidewall 212, as shown in FIG. 3A. In this case, the translation of the second coordinate system is such that offsets along z′ are along the r axis and offsets along r′ are along the z axis.

The reflective outer surface 210 may be described by the following equation,

$$z = \frac{{cr}^{2}}{1 + \sqrt{1 - ( 1 + k ) {c}^{2} {r}^{2}}} + {α}_{1} {r}^{2} + {α}_{2} {r}^{4} + {α}_{3} {r}^{6} + {α}_{4} {r}^{8} \qquad ( 2 )$$

where c is the curvature, k is the conic order, and α₁, α₂, α₃, and α₄ are aspheric coefficients for each polynomial term. For Eq. (2), the variables r and z represent the radial distance along the radial axis of the hybrid optic 200a and the sag of the aspheric profile along the optical axis z of the hybrid optic 200a. Similar to the sidewall 212, the aspheric profile in Eq. (2) may be translated along the optical axis z to adjust the portion of the aspheric profile forming the reflective outer surface 210. For instance, a portion of the aspheric profile proximate to the vertex may not be included to provide space for the core input opening 209 of the folded optical element 205a.

The reflective surface 260 may have a linear profile oriented at an angle, γ, relative to the optical axis, z, such that the reflective surface 260 forms a truncated cone with a circular cross section along a plane defined by the radial axis, r, and a polar axis, θ, of the hybrid optic 200a. The edge of the reflector element 204a defining the output opening may also be constrained to be contiguous with the edge of the core input opening 209 of the hollow core 202 (e.g., the output opening of the reflector element 204a has the same shape and dimension as the core input opening 209) such that light emitted by the light source 104 only intersects the reflective surface 260, the hollow core sidewall 212, or the core output surface 207.

The core output surface 207 may have a spherical profile with a radius of curvature, Rₒᵤₜₚᵤₜ. In this manner, the core output surface 207 defines a surface having spherical curvature, which may focus, at least in part, the first light ray bundle. The spherical profile may also be translated along the optical axis 201 to position the core output surface 207 at a distance, d₃, from the output surface 214 based on the vertex of the spherical profile.

The terms c, k′, α′₄, α′₆, c, k, α₁, α₂, α₃, α₄, γ, Rₒᵤₜₚᵤₜ, may be adjusted in concert to meet the desired metrics under a particular set of constraints according to a particular application. For instance, this exemplary design approach may be used to design a hybrid optic 200a that outputs light rays 215 within a 12 degree divergence angle, defined relative to the optical axis 201 of the hybrid optic 200a. FIG. 3B shows exemplary values of the various terms defining the curvature of the reflective surface 260, the sidewall 212, the reflective outer surface 210, and the core output surface 207 for a particular application where the desired clear aperture is 32.5 mm (the clear aperture is defined as the radius of the output surface 214 that may be used to couple out light from the light source 104), a thickness of less than 16 mm, and light rays 215 being limited to angles less than about 12 degrees from the optical axis of the hybrid optic 200a.

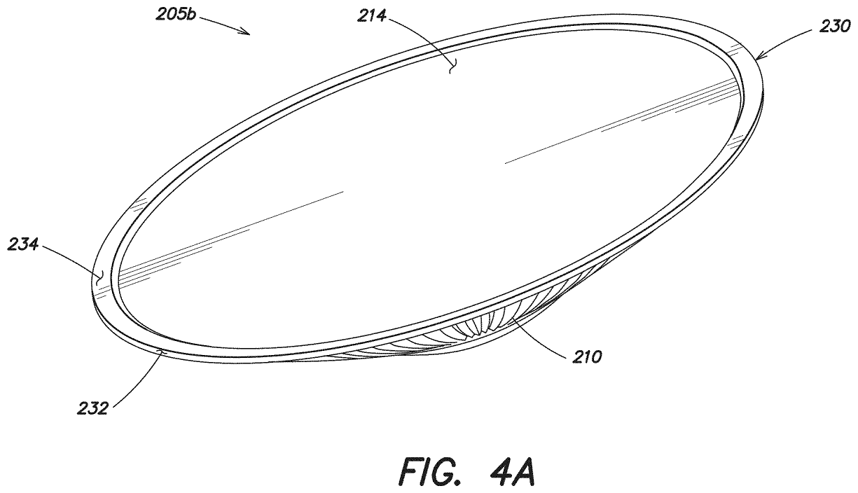

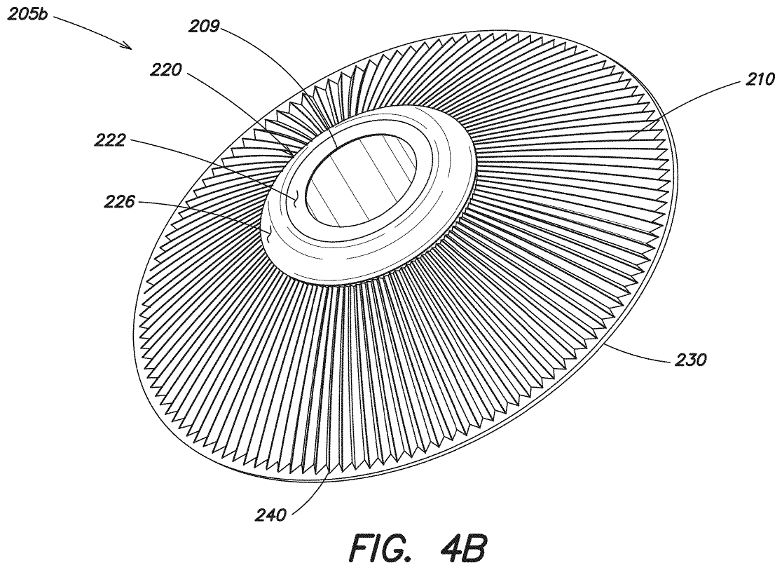

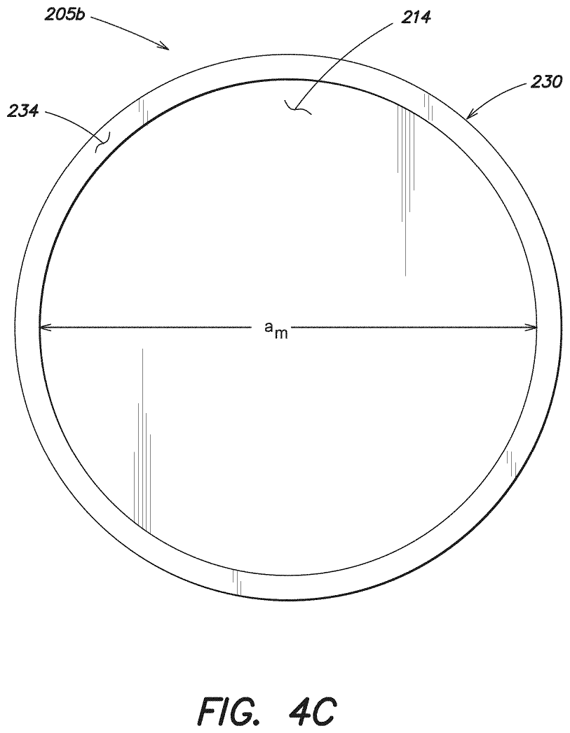

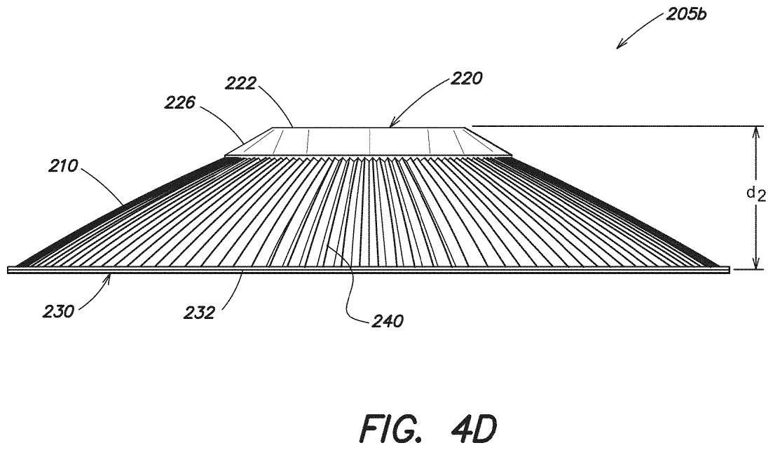

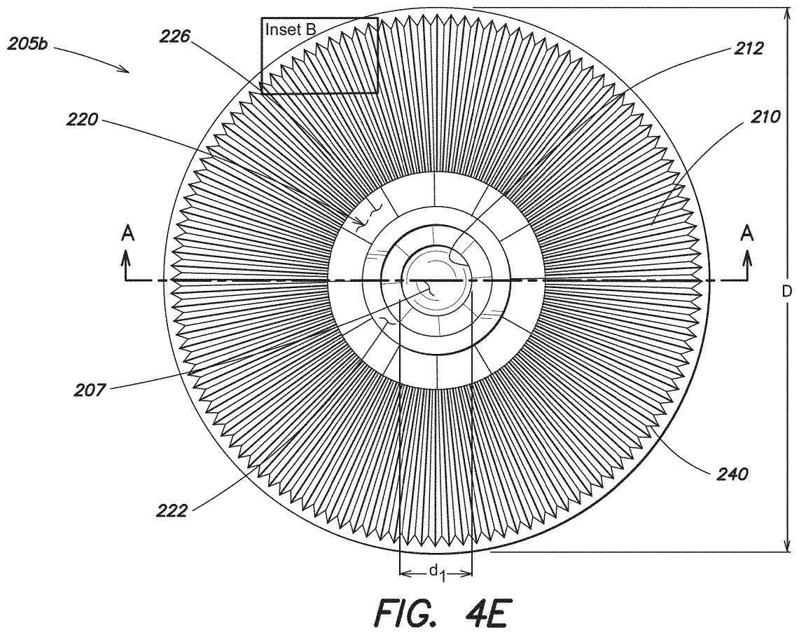

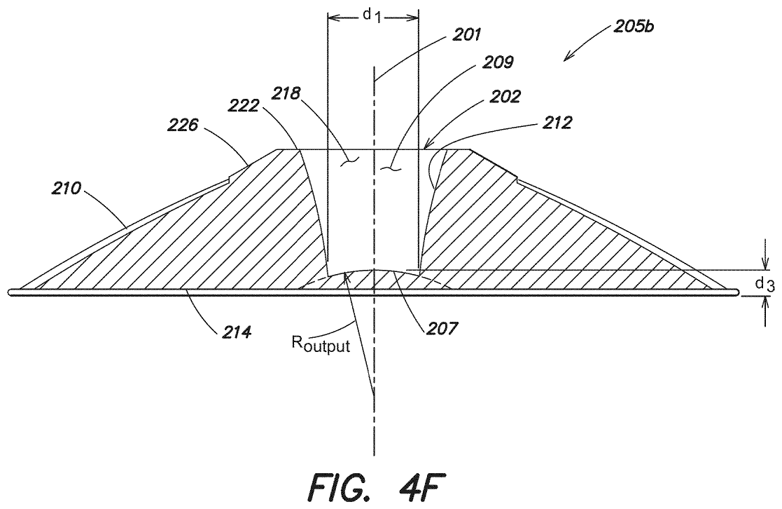

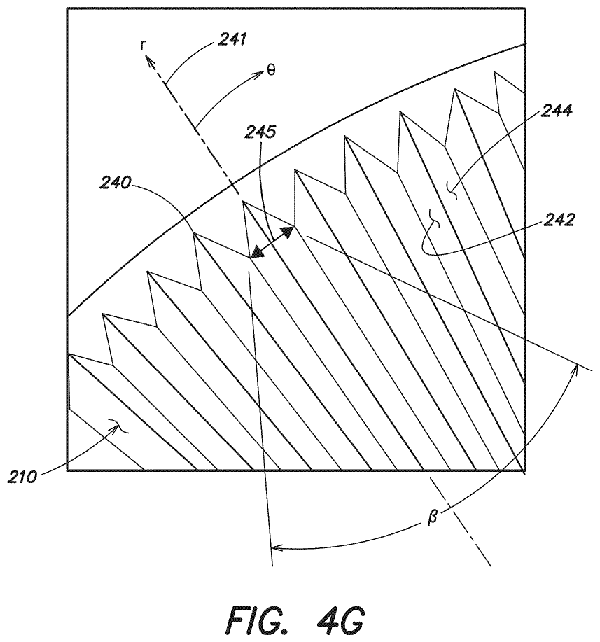

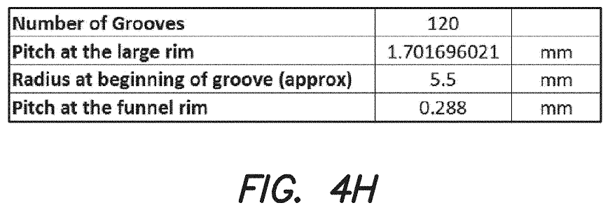

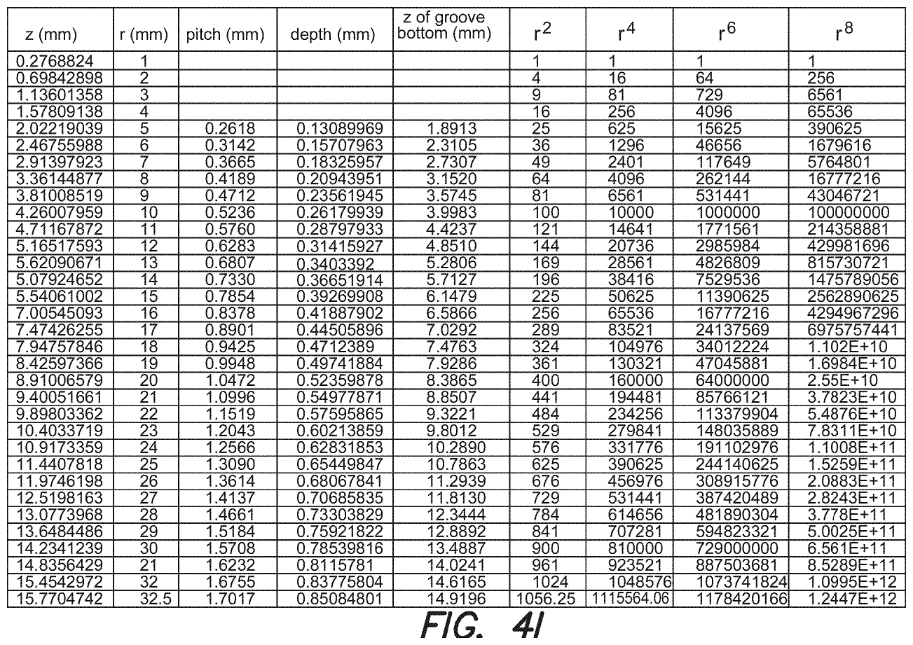

The following describes various exemplary hybrid optics that incorporate similar structural features and operating principles as the hybrid optic 200a. For example, FIGS. 4A-4F show various views of an exemplary folded optical element 205b. It should be appreciated that the top, bottom, front, rear, left, and right views of the folded optical element 205b shown in FIGS. 4A-4F are intended to provide orientation and may not be representative of the orientation in which the folded optical element 205b is disposed in a lighting system.

As shown, the folded optical element 205b may include a hollow core 202, a reflective outer surface 210, and an output surface 214. The hollow core 202 may include a sidewall 212 and a core output surface 207. A lip 230 may be disposed between the output surface 214 and the reflective outer surface 210 to provide a surface to couple the folded optical element 205b to facilitate mechanical coupling of the hybrid optic 200a to a lighting system and/or to support a secondary optical element that further modifies the spatial and angular intensity distribution of the light rays 215. The folded optical element 205b may also include a base 220 disposed between the reflective outer surface 210 and the hollow core 202 to abut the reflector element 204b.

In some implementations, the diameter of the folded optical element 205b, defined as the outer diameter of the lip 230, D, may range between about 35 mm and about 110 mm. In some implementations, the outer diameter, D, is preferably about 67 mm. The overall height, d₂, of the folded optical element 205b, defined as the distance from a surface 222 of the base 220 to a surface 234 of the lip 230 may range between about 8 mm and about 15 mm. In some implementations, the height, d₂, is preferably about 13.5 mm. In the following, various structural features and their dimensions in the folded optical element 205b are described. In some implementations, the dimensions of these various structural features in the folded optical element 205b may be scaled with respect to the outer diameter, the height, or another parameter such that the overall shape of the folded optical element 205b is maintained.

FIG. 4A shows a top perspective view of the folded optical element 205b and, in particular, the output surface 214. In some implementations, the output surface 214 may be substantially flat. In some implementations, the lip 230 may be disposed along the periphery of the output surface 214, as shown in FIG. 4C. For example, a retaining ring or an optic holder (not shown) may clamp the hybrid optic 200a to a housing of the luminaire where the clamping force is applied primarily to the lip 230.

In some implementations, the lip 230 may also separate the output surface 214 from the reflective outer surface 210. As shown, the lip 230 may include surfaces 232 and 234 disposed along the side and top of the folded optical element 205b, respectively. The surfaces 232 and 234 may physically contact a supporting component (e.g., an optic holder) for assembly. In some implementations, the surface 234 may protrude from the output surface 214. In this manner, the lip 230 may prevent the supporting component from contacting the output surface 214, which may affect the light guiding properties of the folded optical element 205b, and/or otherwise reduce damage (e.g., scratches) of the output surface 214 during assembly and/or operation. In some implementations, the lip 230 may have a thickness (i.e., the height of the surface 232) that is at least about 0.5 mm. In some implementations, the surface 234 of the lip 230 may be offset from the output surface 214 at least about 0.5 mm.

FIG. 4B shows a bottom perspective view of the folded optical element 205b and, in particular, the reflective outer surface 210. As described above, the primary function of the reflective outer surface 210 is to reflect light rays in the second light bundle (e.g., light rays 206 and 211) such that the light rays are oriented at a desired angle relative to the output surface 214 (e.g., near normal incidence to the output surface 214) before exiting the folded optical element 205b. In some implementations, the reflective outer surface 210 may extend from the core input opening 209 to the output surface 214 of the folded optical element 205b. In some implementations, the reflective outer surface 210 may cover only a portion of the exterior surface of the folded optical element 205b between the core input opening 209 and the output surface 214.

For example, FIG. 4D shows the reflective outer surface 210 terminates at the lip 230 and the base 220. As shown, the base 220 may be located between the core input opening 209 of the hollow core 202 and the reflective outer surface 210. The base 220 may include a surface 222 to abut a corresponding surface 272 of the reflector element 204b for assembly. As shown, the surface 222 may have a circular shape. However, it should be appreciated in other implementations the surface 222 may be shaped as a polygon (e.g., a triangle, a square, a hexagon, an octagon).

The base 220 may also include a surface 226 that extends along a port of the exterior outer surface of the folded optical element 205b, adjoining the reflective outer surface 210. In some implementations, the surface 226 may offset the reflective outer surface 210 from the surface 222. In some implementations, the offset between the reflective outer surface 210 and the surface 222, as measured along an axis parallel to the optical axis 201, may be about 2.5 mm. The diameter of the reflective outer surface 210 at offset may be about 27 mm.

In some implementations, the offset may be chosen based on the angular range subtended by the light incident on the reflective surface 260 of the reflector element 204b. In other words, the offset may be set such that light is primarily incident on the reflective outer surface 210 and not the surface 226 of the base 220. In some implementations, the surface 226 may also be used to label the hybrid optic 200a for identification.

In some implementations, the reflective outer surface 210 may be coated in order to be reflective to the light emitted by the light source 104. For example, the reflective outer surface 210 may be coated with a reflective material (e.g., a metal, a diffusely reflecting material) to reflect light rays 206 and 211. For example, the reflective outer surface 210 may be coated with various metals including, but not limited to silver, aluminum, chromium, and gold. In some implementations, the coating may be a dielectric Bragg mirror configured to have a photonic band gap that substantially overlaps with the wavelengths of light emitted by the light source 104. Adhesion layers may be disposed between the reflective outer surface 210 and the coating to reduce delamination of the coating during operation and/or handling. For instance, adhesion layers formed of thin layers of chromium or titanium (less than 10 nm thick) may be used in implementations where the reflective coating is another metal, such as gold. In some implementations, the coating on the reflective outer surface 210 may be deposited using various deposition methods including, but not limited to, thermal evaporation, e-beam evaporation, sputtering, dip coating, chemical vapor deposition, and any other method known to one of ordinary skill in the art.

In some implementations, the reflective outer surface 210 may include one or more prisms 240 to reflect light via TIR. FIGS. 4D and 4E show a front view and a bottom view, respectively, of the reflective outer surface 210 and the prisms 240. In some implementations, the prisms 240 may be formed as a series of grooves that each have a V-shaped cross section along the plane defined by the radial axis, r, and the polar axis, θ, of the hybrid optic 200a and a groove axis 241 aligned parallel to the radial coordinate, r, of the hybrid optic 200a and conforming to the curvature of the reflective outer surface 210, as shown in FIG. 4D. The grooves 240 may be configured to reflect light rays 206 and 211 via TIR along two facets 242 and 244 forming each groove as shown in FIG. 4G.

The prism 240 may be characterized by a groove angle, β, which is defined as the angle between the groove facets 242 and 244. The angle β may provide an additional parameter to tune the spatial and/or angular intensity distribution of the light rays 215. For instance, the angle β may range between about 90.75 degrees and about 91.75 degrees and may preferably be about 91.25 degrees to provide an output light beam from the hybrid optic 200a that has a relatively smooth spatial and angular intensity distribution. If the angle β is about 90 degrees, which is typically used in conventional TIR collimators (e.g., 3M BEF films), a “double hump” beam may be generated where the intensity decreases at the center of the light beam along the optical axis 201 of the hybrid optic 200a, which is aesthetically undesirable.

FIG. 4H shows an exemplary set of constraints for the prisms 240 formed from a plurality of grooves disposed along the reflective outer surface 210 of the hybrid optic 200a. Also shown is the pitch 245 of the grooves near the output surface 214 and the core input opening 209. FIG. 4I shows tabulated values of the aspheric profile for the reflective outer surface 210 and the pitch 245 of the grooves for this particular implementation. FIG. 4I also shows tabulated values of the polynomial terms describing the curvature of the reflective outer surface 210 according to Eq. (2) for various sized folded optical elements 205b (e.g., the clear aperture).

In some implementations the reflective outer surface 210 includes a prismatic structure (e.g., the prisms 240), the prismatic structure may be fabricated concurrently with the main body of the folded optical element 205b. For example, the folded optical element 205b and the reflective outer surface 210 may be formed by injection molding or casting. In some implementations, the prismatic structure may be formed post-fabrication using methods including, but not limited to milling, stamping, grinding, doping (e.g., to form a prismatic structure based on a contrast in refractive index), and any other method known to one of ordinary skill in the art.

FIG. 4F shows the hollow core 202, which includes a sidewall 212 defining the core input opening 209 and a core output surface 207. The sidewall 212 and the core output surface 207 may together define the cavity 218. In some implementations, the sidewall 212 may have an aspheric curved profile, as described above. In some implementations, the aspheric curved profile may be swept around the optical axis 201 to form a curved surface with a circular cross-section. However, it should be appreciated in other implementations, the cross-section may be polygonal in shape (e.g., a triangle, a square, a hexagon, an octagon), which varies in size along the optical axis 201 according to the aspheric curved profile. In some implementations, the core input opening 209 may have a characteristic width (e.g., a diameter if circular in shape) of about 13.7 mm.

In some implementations, the core output surface 207 may share an edge with the sidewall 212. The shape and/or dimensions of the core output surface 207 may thus depend, in part, on the shape and/or dimensions of the sidewall 212 and the aspheric curved profile. For example, the dimensions of the core output surface 207 may vary if the position of the core output surface 207 is shifted along the optical axis 201 due to the variation in the aspheric curved profile. In some implementations, the core output surface 207 may have a characteristic width (e.g., a diameter if the cross-section of the sidewall 212 and/or the core output surface 207 are circular in shape), d₁, of about 8 mm.

In some implementations, the core output surface 207 may be substantially flat such that the plane of the core output surface 207 is substantially parallel to the output surface 214 to reduce manufacturing complexity. In some implementations, the core output surface 207 may have a curvature (e.g., an aspheric profile or a spherical profile), as described above and shown in FIG. 4F, to increase the light coupling efficiency by refracting light rays from the first light ray bundle towards a more preferable angle relative to the output surface 214 (e.g., closer to normal incidence). The curvature may also help to improve the appearance of the light beam outputted by the hybrid optic 200a by providing a smoother spatial and angular intensity distribution.

In some implementations, the core output surface 207 may be offset at a distance from the output surface 214 (i.e., the distance d₃) as shown in FIG. 4F. The distance d₃ may be adjusted, in part, to improve ease of manufacturability (e.g., reducing the fragility of the output surface 214 to cracks and/or fracture). In some implementations, the distance d₃ may range from about 1 mm to about 2 mm. By enclosing the hollow core 202, the hybrid optic 200a may also reduce exposure of the light source 104 to the ambient environment, thereby reducing degradation of the light source 104 and increasing operating lifetime.

In some implementations, the hollow core 202 may extend entirely through the folded optical element 205b such that there is no core output surface 207, but, rather, an opening on the output surface 214 coincident with the hollow core 202. In this manner, unwanted reflections from the core output surface 207 and/or the output surface 214 for light rays in the first light bundle may be substantially reduced.

The folded optical element 205b in the hybrid optic 200a may be formed from materials that are transparent to the wavelength(s) of light emitted by the light source 104. For example, the folded optical element 205b may be tailored for transmission for visible wavelengths, e.g., 400 nm-700 nm, or near infrared wavelengths, e.g., 700 nm-2 μm. Additional considerations may also be made with respect to the refractive index of the material, which may affect the dimensionality of the hybrid optic 200a. Generally, a material having a higher refractive index exhibits a smaller critical angle for TIR with respect to air, which may result in a thicker hybrid optic 200a with a larger hollow core 202 to accommodate a larger range of intermediate emission angles.

Depending on the desired operating wavelength range and refractive index, various hard plastics, glasses, and ceramics may be used including, but not limited to as polycarbonate, acrylic polymer, cyclo olefin polymer (Zeonex), polystyrene, silicate-based glasses, calcium fluoride, magnesium fluoride, silicon, germanium, or zinc selenide. The refractive index of the material may also be further modified by doping or introducing porosity into the material.

Depending on the material used to form the folded optical element 205b, several manufacturing methods may be used for fabrication including, but not limited to injection molding, milling, lapping, grinding, and any other method known to one of ordinary skill in the art. In some implementations, some of the surfaces of the folded optical element 205b (e.g., the hollow core sidewall 212, the output surface 214) may be further polished to reduce the surface roughness, thereby improving the optical quality of the folded optical element 205b, which may engender a higher light coupling efficiency, for instance, by reducing stray light scattering (i.e., light that propagates along undesirable optical paths resulting in optical loss). A lower surface roughness may also lead to a smoother spatial and angular intensity distribution by increasing the proportion of specularly reflected light, which the hybrid optic 200a is designed to manipulate, to the proportion of diffusely reflected light. Various polishing methods may be used depending on the material used to form the folded optical element 205b including, but not limited to, chemical mechanical polishing, abrasives, machining (e.g., diamond turning), and any other method known to one of ordinary skill in the art.

In some implementations, some of the surfaces of the folded optical element 205b (e.g., the lip 230, the base 220) may be textured to scatter stray light within the folded optical element 205b. For example, light reflected by the lip 230 and/or the base 220 may give rise to unwanted non-uniformities in the output light 215. By texturing the lip 230 and/or the base 220, stray light incident on these features may be scattered, thus reducing the appearance of the non-uniformities. In some implementations, the textured surfaces may diffusely reflect and/or diffusely transmit light within a diffusion angle that ranges between about 3 degrees and about 100 degrees.

In some implementations, the surface(s) of the folded optical element 205b may be textured directly during fabrication (e.g., a mold for injection molding may include the desired surface texture via a laser etching process) or post-fabrication (e.g., the folded optical element 205b is machined or etched). In some implementations, the proportion of light reflected diffusely and specularly from the textured surfaces may also be controllable based on the geometry and dimensions of the surface texture applied and the desired spatial/angular distribution of light.

In some implementations, coatings may be applied to the various surfaces of the folded optical element 205b. In one example, coatings may be applied as a form of cladding. For instance, a coating may be disposed onto the output surface 214 to protect the output surface 214 from damage (e.g., scratches) and/or to reduce contamination (e.g., dust, dirt) of the output surface 214, which may cause unwanted outcoupling of light, e.g., light coupled at undesirable angles relative to the center axis of the hybrid optic 200a. The cladding may be formed from a material having a refractive index preferably similar to air such that the critical angle for TIR at the output surface 214 is not substantially affected by the coating.

Coatings may be applied after fabrication of the main body of the folded optical element 205b using various deposition methods including, but not limited to thermal evaporation, e-beam evaporation, sputtering, dip coating, chemical vapor deposition, and any other method known to one of ordinary skill in the art. In some implementations, a coating may be formed by doping the surface of the main body such that a layer having a refractive index different from the main body of the folded optical element 205b is formed. For patterned structures, various patterning methods may be used including, but not limited to, photolithography, e-beam lithography, and nanoprinting, combined with various etching methods including, but not limited to, reactive ion etching, wet chemical etching, and ion milling.

The reflector element 204b primarily reflects light emitted at larger emission angles from the light source 104 such that the light is either directly radiated out of the hybrid optic 200a (e.g., light ray 208) or indirectly radiated out of the hybrid optic 200a (e.g., light ray 211), thus increasing the light coupling efficiency. In some implementations, the reflector element 204b and the folded optical element 205b may be formed as a single component. In some implementations, the reflector element 204b may be a separate component mechanically and optically coupled to the folded optical element 205b.

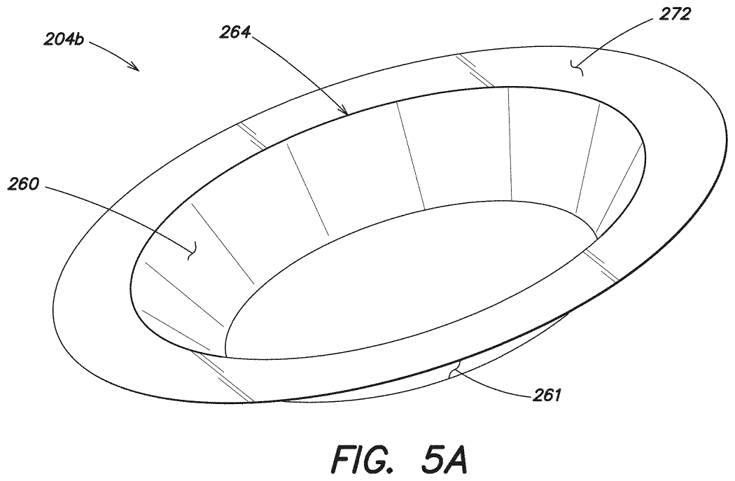

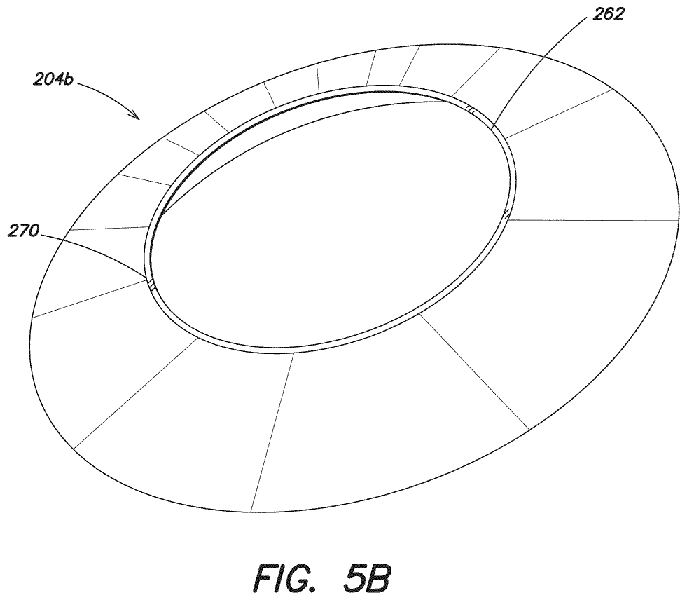

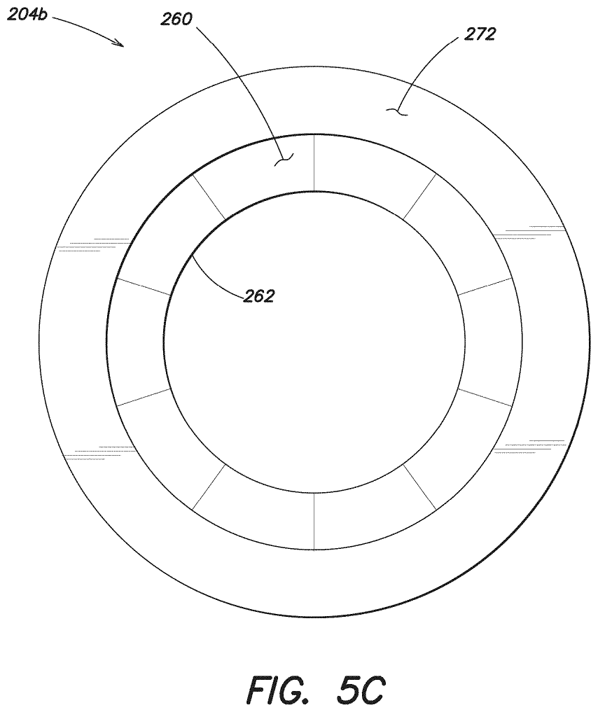

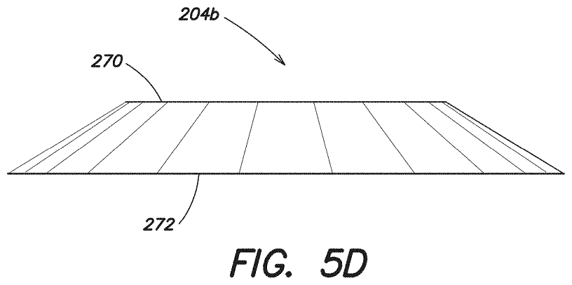

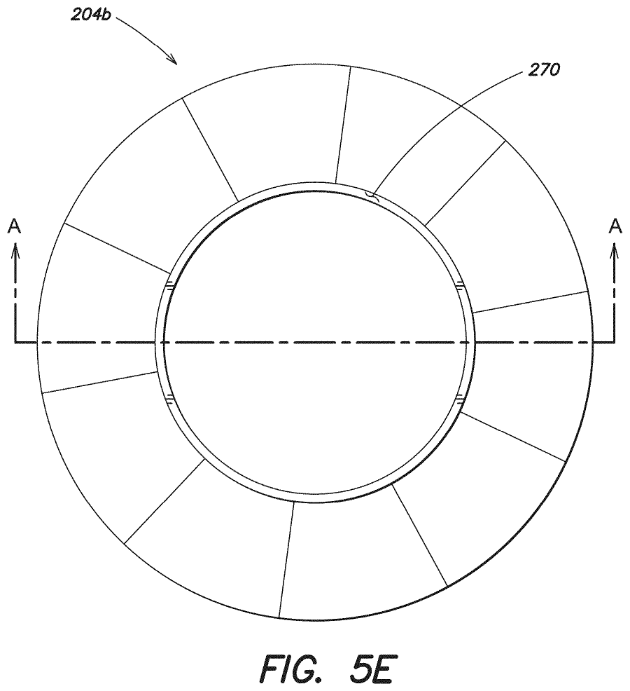

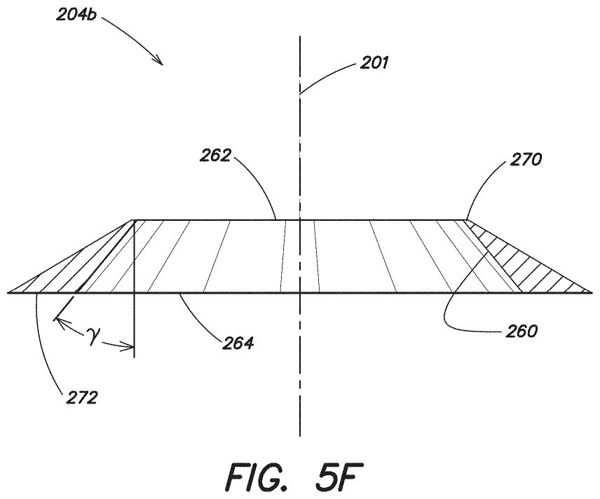

FIGS. 5A-5F show various views of the reflector element 204b for implementations where the reflector element 204b is designed to be a separate component that is attached to the folded optical element 205b during assembly. It should be appreciated that the top, bottom, front, rear, left, and right views of the reflector element 204b shown in FIGS. 5A-5F are intended to provide orientation and may not be representative of the orientation in which the reflector element 204b is disposed in a lighting system.

FIG. 5A shows a top perspective view of the reflector element 204b. As shown, the reflector element 204b may be an axisymmetric component with radial symmetry about an axis coincident with the optical axis 201 of the hybrid optic 200a. The reflector element 204b may include a sidewall 261 that defines an input opening 262 and an output opening 264. Light from the light source 104 enters the reflector element 204b through the input opening 262 and exits through the output opening 264 into the hollow core 202 of the folded optical element 205b. The sidewall 261 includes a reflective surface 260, shown as the interior surface of the reflector element 204b, to reflect a portion of the light from the light source 104.

In some implementations, one or more portions of the reflector element 204b, such as the reflector surface 260, may have a circular cross-section. However, it should be appreciated in other implementations the reflector element 204b may have a polygonal cross-sectional (e.g., a triangle, a square, a hexagon, an octagon). In some implementations, the overall height of the reflector element 204b, s, as defined between the input opening 262 and the output opening 264 of about 2.2 mm. In some implementations, the input opening 262 may be sufficiently large to surround a light source 104. In this manner, the light emitted by the light source 104 predominantly enters the reflector element 204b. In some implementations, the input opening 262 may have a characteristic width (e.g., a diameter if circular in shape) of about 10 mm. In some implementations, the output opening 264 may be shaped and/or dimensioned to match the core input opening 209. Thus, the light that enters the reflector element 204b is also coupled into the folded optical element 205b. In some implementations, the output opening 264 may have a characteristic width (e.g., a diameter if circular in shape) of about 13.7 mm.

In the following, various structural features and their dimensions in the reflector element 204b are described. In some implementations, the dimensions of these various structural features in the reflector element 204b may be scaled with respect to the characteristic width of the input opening 262 or the output opening 264, the height, or another parameter such that the overall shape of the reflector element 204b is maintained. In some implementations, the dimensions of the reflector element 204b may be scaled with other components of the hybrid optic 200b (e.g., the folded optical element 205b). For example, a smaller sized folded optical element 205b may be coupled to a correspondingly smaller sized reflector element 204b.

The reflector element 204b may further include a surface 272 adjoining the reflective surface 260 to abut the surface 222 of the folded optical element 205b for assembly. In some implementations, the surface 272 may have an outer width (e.g., a diameter if circular in shape) of about 18 mm. The surfaces 272 and 222 may be coupled together using various attachment methods including, but not limited to ultrasonic welding, polymer adhesives, mechanical snap-in features, a ring to press and secure the lens onto the reflector, or any other methods known to one of ordinary skill in the art.

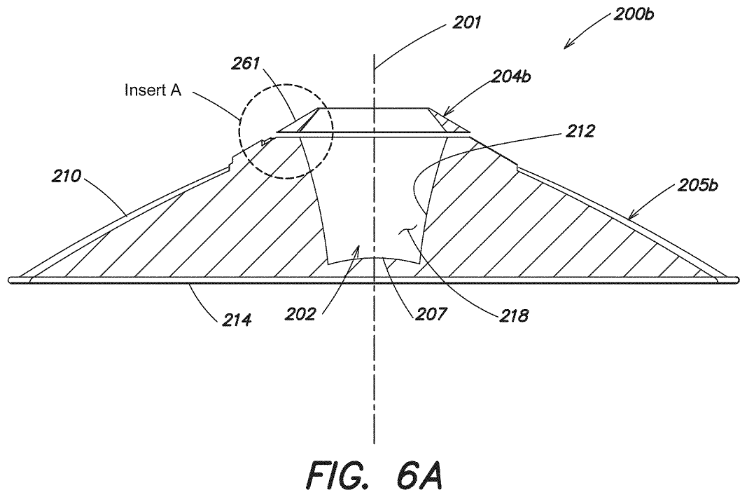

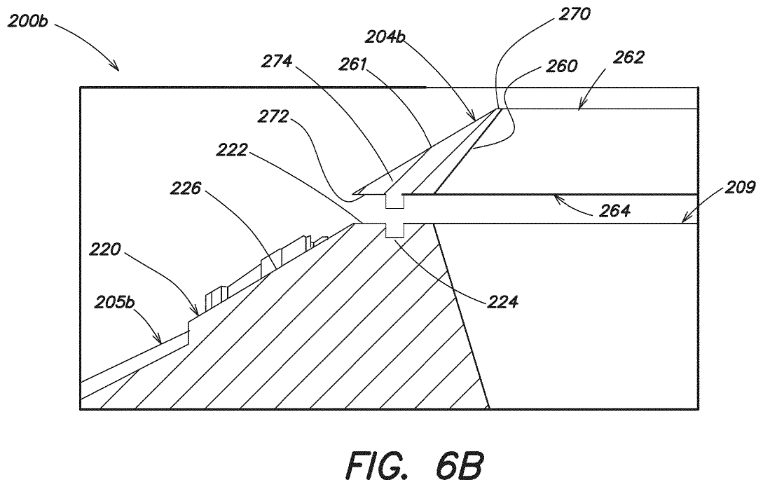

In some implementations, the surface 272 may include a first coupling feature, such as a nipple 274 shown in FIGS. 6A and 6B, to facilitate alignment with and attachment to the folded optical element 205b. The surface 222 may include a corresponding second coupling feature, such as a cavity 224 (also referred to as a “slot 224”), to mechanically register and receive the nipple 274 from the reflector element 204b as shown in FIG. 6B. As shown in FIGS. 6A and 6b, the nipple 274 and the slot 224 may be shaped as an annulus (e.g., an annular slot, an annular nipple). In some implementations, a plurality of nipples 274 and/or slots 224 may be used to facilitate alignment and assembly of the reflector element 204b to the folded optical element 205b. In some implementations, the surfaces 272 and 222 may also be roughened to increase the surface area available for bonding.

The reflector element 204b may also include a surface 270 adjoining the reflective surface 260. The surface 270 may either contact the light source 104 or a support structure supporting the light source 104 (e.g., to reduce heating of the reflector element 204b from the light source 104). In some implementations, the surface 270 may have an outer width (e.g., a diameter if circular in shape) that varies depending on the size of the light source 104. For example, if the light source 104 has a 9 mm diameter, the surface 270 may have a diameter of about 10.3 mm. If a larger light source 104 is used, the characteristic width of the surface 270 maybe scaled accordingly. In some implementations, the reflector element 204b may support operation at elevated temperatures (e.g., up to about 150° C.) to accommodate heating from the light source 104.

FIG. 5F shows a cross-sectional view of the reflector element 204b. As shown, the sidewall 261 may be shaped as a truncated cone where the reflective surface 260 has a linear profile. The reflective surface 260 may be oriented at an angle, γ, from the optical axis 201 of the hybrid optic 200a. In some implementations, the angle γ may be about 39.8 degrees. However, it should be appreciated the angle γ may vary depending, in part, the desired metrics of the hybrid optic 200b and/or the set of constraints imposed on the design of the hybrid optic 200b as described above with respect to the various parameters used in FIGS. 3A and 3B.

The reflector element 204b may be formed from various metals including, but not limited to aluminum, brass, and stainless steel. In other implementations, the reflector element 204b may be formed from non-reflective materials, such as polycarbonate, acrylic polymer, cyclo-olefin polymer (Zeonex), polystyrene, and coated with a reflective material such as chromium, aluminum, silver, gold, or a dielectric Bragg mirror coating. Depending on the material used to form the reflector element 204b, several manufacturing methods may be used for fabrication including, but not limited to injection molding, milling, polishing, lapping, grinding, or any other method known to one of ordinary skill in the art. A reflective coating may also be applied to one or more of the surfaces of the reflector element 204b (e.g., the reflective surface 260) using any deposition method known in the art including, but not limited to thermal evaporation, e-beam evaporation, sputtering, dip coating, or chemical vapor deposition. Adhesion layers may be disposed between the surfaces of the reflector element 204b and the coating to reduce delamination of the coating during operation and/or handling. For instance, adhesion layers formed of thin layers of chromium or titanium (less than 10 nm thick) may be used in implementations where the reflective coating is another metal, such as gold.

In some implementations, the reflector element 204b may be formed from the same material as the folded optical element 205b to facilitate ease of manufacture and assembly. For example, materials having a substantially similar chemical composition may be more readily coupled together via ultrasonic welding. In implementations where the folded optical element 205b and the reflector element 204b are manufactured as a single component, the reflective surface 260 of the reflector element 204b may be coated with a reflective material using the aforementioned deposition methods in combination with a mask applied to the sidewall 212 and the core output surface 207 to preserve transparency.

In some implementations, the reflective surface 260 of the reflector element 204b may be substantially smooth in order to specularly reflect light. For example, the reflective surface 260 of the reflector element 204b may be polished to improve the optical quality by reducing the surface roughness. Various polishing methods may be used and, in some instances, many depend on the material from which the reflector element 204b is formed including, but not limited to chemical mechanical polishing, abrasives, machining (e.g., diamond turning), and any other method known to one of ordinary skill in the art.

In some implementations, the reflective surface 260 of the reflector element 204b may instead be roughened in order to diffusely reflect light. For example, non-uniformities in the light output 215 may arise due to the uneven distribution of light along the various optical paths (e.g., the first and second light bundles). By tailoring the reflective surface 260 to diffusely reflect light, the light may be more evenly distributed between the first and second light bundles. For example, the proportion of the light in the first light bundle and the second light bundle may be proportional to the area of the output surface 214 from which the first and second light bundles exit the hybrid optic 200b. In some implementations, the reflector element 204b may be textured directly during fabrication (e.g., a mold for injection molding may include the desired surface texture via a laser etching process) or post-fabrication (e.g., the folded optical element 204b is machined or etched). In some implementations, the reflector element 204b may be formed from diffusely reflecting material, such as Spectralon®.

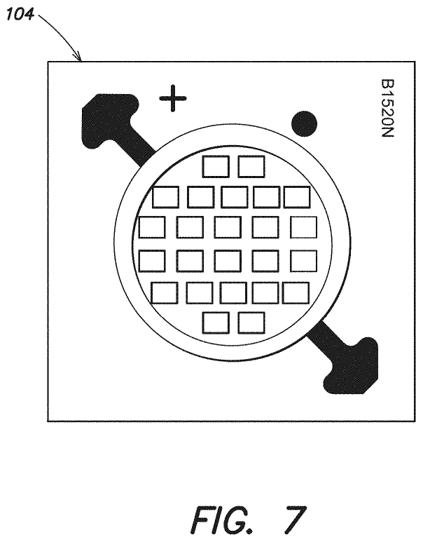

It should be appreciated that the hybrid optic described in the present disclosure may be used with a variety of electrooptical light devices including, but not limited to, light emitting diodes (LEDs, such as an XLamp LED from Cree), organic light-emitting diode (OLEDs), or polymer light-emitting diode (PLEDs). The light source 104 may include one or more LED's that each emit light. For example, FIG. 7 shows an exemplary light source 104 wherein a plurality of LED's are disposed within a circular area of the light source 104. The hybrid optic may be designed and tailored to a particular light source 104. The input opening 262 of the reflector element 204b may also be dimensioned to be sufficiently large such that light emitted by the light source 104 substantially enters an interior cavity defined by the reflective surface 260 of the reflector element 204b and the hollow core 202 of the folded optical element 205b.

A Hybrid Optic with Diffuse Reflective Surface(s)

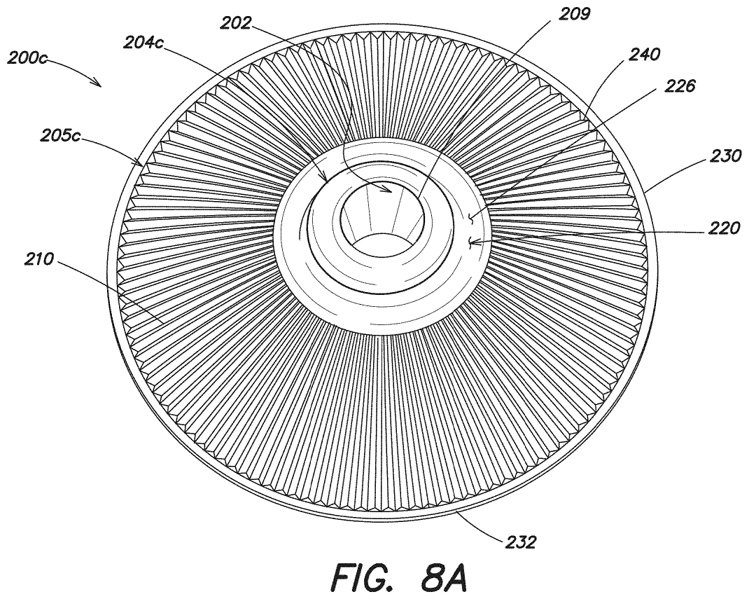

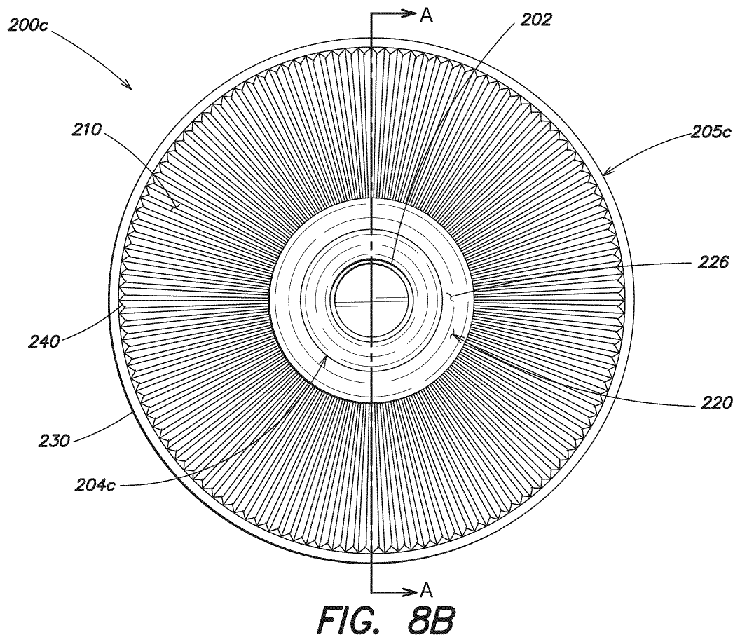

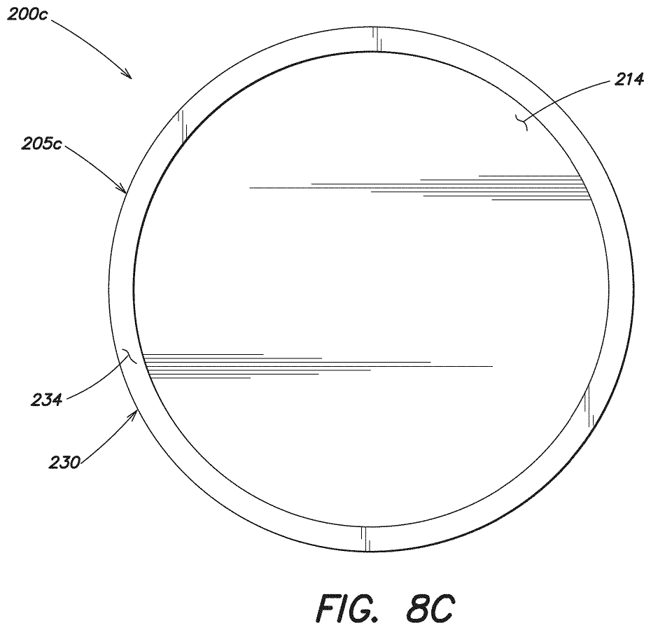

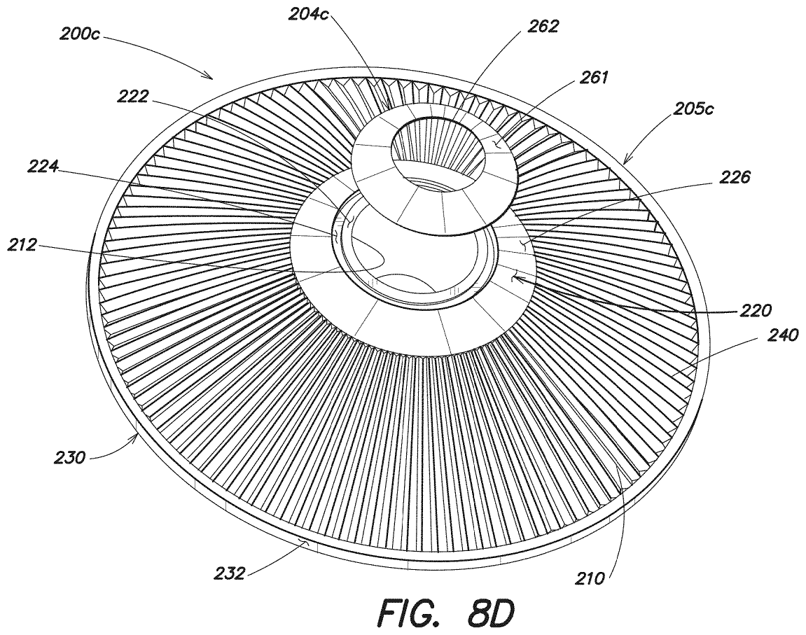

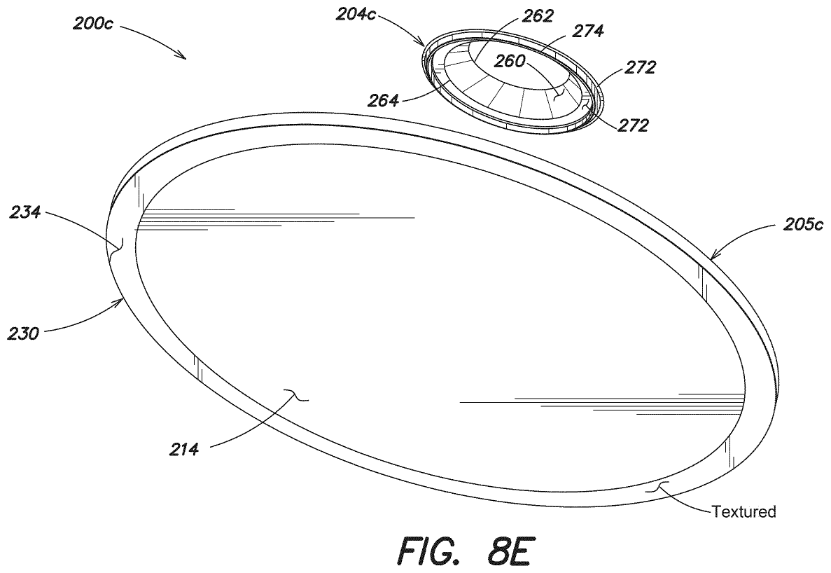

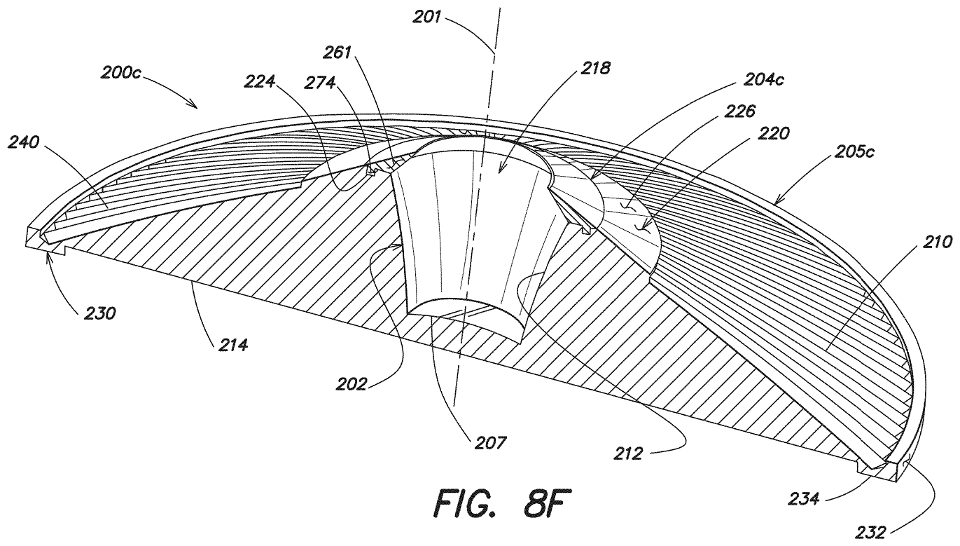

FIGS. 8A-8F show several views of an exemplary hybrid optic 200c with multiple textured surfaces to scatter stray light and, hence, reduce unwanted non-uniformities in the output light (e.g., spots/rings, scalloping, concentrations of light giving rise to glare). As shown, the hybrid optic 200c may include a folded optical element 205c coupled to a reflector element 204c. As before, the folded optical element 205c may include a hollow core 202, a base 220, a reflective outer surface 210, a lip 230, and an output surface 214. The hollow core 202 may include a sidewall 212 defining a core input opening 209 and a core output surface 207 that shares an edge with the sidewall 212. The reflector element 204c may include a sidewall 261 defining an input opening 262 and an output opening 264 with a reflective surface 260. The reflector element 204c may include a surface 272 with an annular nipple 274 to couple the reflector element 204c to an annular slot 224 on the surface 222 of the folded optical element 205c.

One common source for non-uniformities in the output light is the distribution of light emitted by the light source 104. The light source 104 may emit light with a non-uniform spatial and angular distribution due to the physical arrangement and/or structure of the light emitting elements within the light source 104. For example, the spatial and/or angular distribution of the light may exhibit a pattern that corresponds to the structural layout of the light emitting elements in the light source 104. The spatial and/or angular distribution may further vary as a function of the wavelength of the light. For example, the light source 104 may include multiple LED elements configured to emit light at specific wavelengths. The layout of the LED elements corresponding to different wavelengths of light may thus vary, resulting in wavelength-dependent variations in the spatial and/or angular distribution of the light.

One approach to reduce the effect of non-uniformities cause by the light source 104 is to configure the reflector element 204c to diffusely reflect light instead of specularly reflect light. Specular reflection occurs when incident light is reflected along a single direction as dictated by Snell's law. Thus, higher intensity light propagating along a particular direction may be reflected with a similar intensity giving rise to glare. In contrast, diffuse reflection occurs when incident light is reflected along multiple directions. In other words, the intensity of the light is divided along multiple optical paths instead of being concentrated along a single optical path.

In this manner, diffuse reflection of the light from the light source 104 may soften the light (i.e., reduce the amplitude of the non-uniformities in the light). Said in another way, the diffuse reflection of light by the reflector element 204c may distribute the amount of light propagating along the various optical paths supported by the hybrid optic 200c more evenly. Diffuse reflection may also reduce the amount of light that is reflected back to the light source 104 due, in part, to stray light scattering in the hybrid optic 200c by diffusely reflecting at least a portion of the light back towards the folded optical element 205c. In some instances, the non-uniformities may be smoothed to such an extent that variations in the intensity of the light are no longer observable to the naked eye.

Therefore, in some implementations, the reflective surface 260 of the reflector element 204c may diffusely reflect light. In some implementations, the reflective surface 260 may be tailored to be a Lambertian surface. This may be accomplished in several ways including, but not limited to forming the reflector element 204c from a diffusely reflective material, tailoring the surface finish of the reflective surface 260 to diffusely reflect light (e.g., texturing the reflective surface 260), and coating the reflective surface 260 with a diffusely reflective material. For example, the reflector element 204c may be formed from various diffuse reflectance materials including, but not limited to Spectralon®. In another example, the reflector element 204c may instead be coated with a diffuse reflectance material. In yet another example, the reflective surface 260 may be formed from a reflective material (e.g., a material with a white color) that is then machined and/or formed to have a surface roughness such that the reflector element 204c has a white matte finish.

In some implementations, the surface finish may be tuned to provide a desired amount of diffuse reflection and specular reflection based, in part, on the desired spatial and/or angular distribution of light. For example, the reflector element 204c may specularly reflect between 0% to 100% of the light incident on the reflective surface 260 and diffusely reflect the remaining light. Furthermore, the reflective surface 260 may be tailored such that a portion of the reflective surface 260 is substantially diffusely reflective while another portion is substantially specularly reflective. In this manner, the output light may intentionally be patterned as desired.

As alluded to above, another common source of structured light is the reflection of stray light from portions of the hybrid optic 200c that are not intended to interact with the light (i.e., an optical “dead zone”). For example, the lip 230 and/or the base 220 of the folded optical element 205c may receive light from the hollow core 202, the reflective outer surface 210, and/or the output surface 214 due, in part, to the tolerances of manufacture, defects in the surface quality of the reflective surface 260, the hollow core 202, the reflective outer surface 210, and/or the output surface 214, or misalignment between the light source 104 and the hybrid optic 200c. The resultant reflection of light by, for example, the lip 230 and/or the base 220 may give rise to the appearance of rings and/or spots in the output light.

Although one approach to reduce the formation of structured light due to stray light scattering is to increase the precision that the folded optical element 205c and the reflector element 204c are fabricated and assembled, this may not be practical due to higher manufacturing costs. Another approach is to tailor the surfaces of features in the hybrid optic 200c that are intended to be optical dead zones to be diffusely reflective. For example, the surfaces of the lip 230 (e.g., surfaces 232, 234) and/or the surfaces of the base 220 (e.g., surfaces 222, 226) may be textured and/or coated with a diffuse reflectance material to diffusely reflect stray light. Similar to diffuse reflection by the reflector element 204c, the diffuse reflection of stray light may soften the appearance of unwanted non-uniformities caused by the lip 230 and/or the base 220. In some implementations, the textured surfaces of the lip 230 and/or the base 220 may be a Lambertian surface.

In some implementations, the diffusely reflective surfaces of the hybrid optic 200c may be tailored to have a low transmittance in order to prevent unwanted optical losses due to light being coupled out of the optical dead zones instead of the output surface 214. This may be accomplished, in part, by forming the folded optical element 205c and/or the reflector element 204c from materials with sufficiently different refractive indices compared to air. In some implementations, the surfaces of the optical dead zones may also be coated with a reflective material (e.g., a metal, a diffuse reflectance material) to mitigate unwanted losses through these features of the hybrid optic 200c. For example, the surfaces of the lip 230 and the base 220 may be tailored to be diffusely reflecting.

In some implementations, the core output surface 207 may also be textured to reduce scalloping and/or glare. Unlike the lip 230 and/or the base 220, however, the core output surface 207 may be transparent to incident light. In other words, a textured core output surface 207 may diffusely transmit light. In some implementations, the core output surface 207 may be partially diffusely transmissive and diffusely reflective to adjust the amount of light in the first and second light ray bundles. For example, the core output surface 207 may be tailored to diffusely reflect a portion of the light incident on the core output surface 207 in order to reduce the intensity of light exiting the hybrid optic 200c through the core output surface 207 and, hence, reduce unwanted glare. Instead, this diffusely reflected may be redirected into the second light ray bundle. Thus, the overall light coupling efficiency may remain substantially unchanged despite the redistribution of light between the first and second light ray bundles.

A Hybrid Optic with a Glare Control Diffuser

As described above, the formation of structured light may be attributed, in part, to the uneven distribution of light propagating along the multiple optical paths supported by the hybrid optic. For example, the intensity of light in the first light ray bundle (i.e., the light that radiates out of the hybrid optic through the core output surface) may be appreciably different from the intensity of light in the second light ray bundle (i.e., the light that undergoes multiple reflections after being refracted by the sidewall of the hollow core). The difference in intensities may give rise to undesirable scalloping and glare effects. In order to reduce the appearance of these non-uniformities, a glare control diffuser may be incorporated into the hybrid optic to disperse the light from the first light ray bundle along multiple directions in order to soften variations in the spatial and/or angular distribution of light.

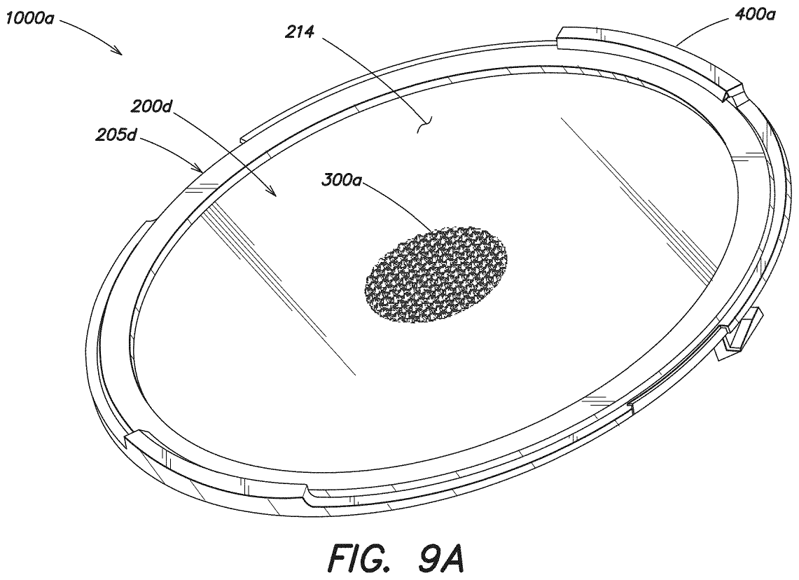

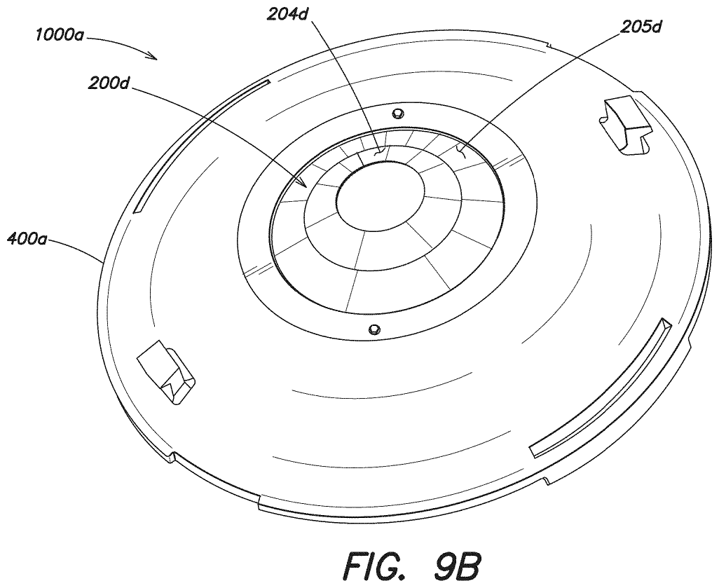

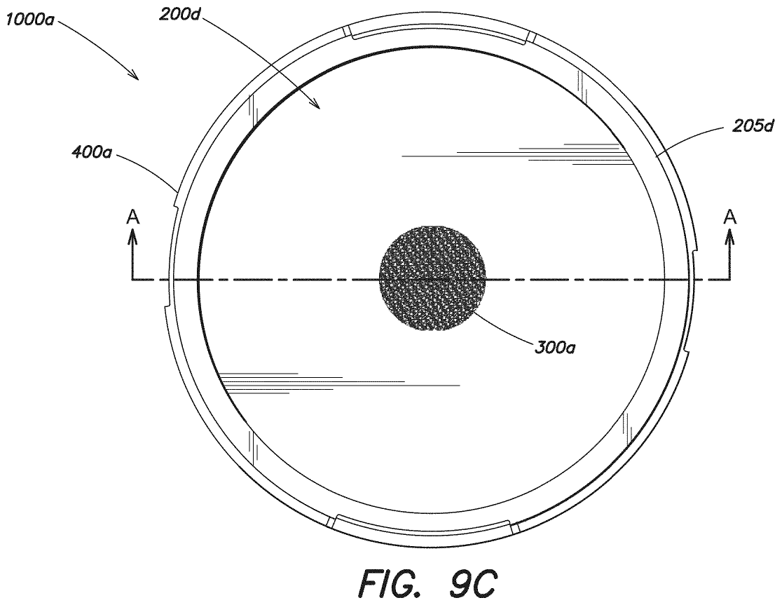

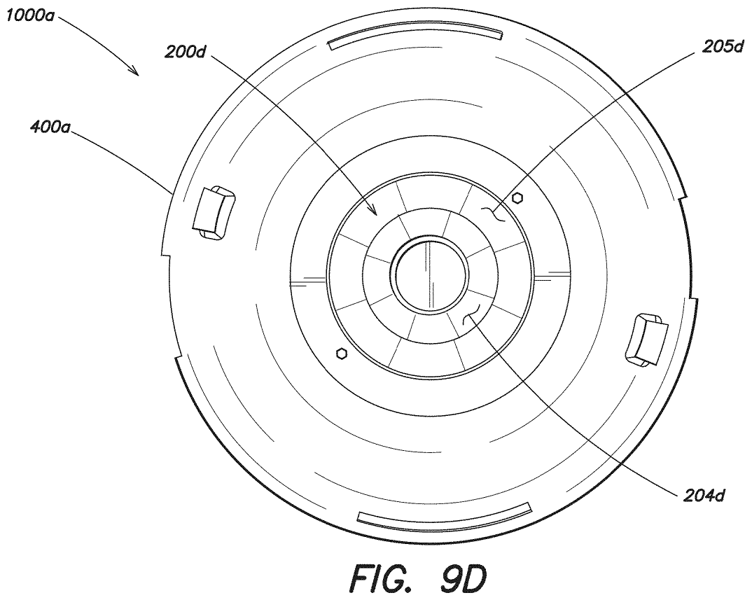

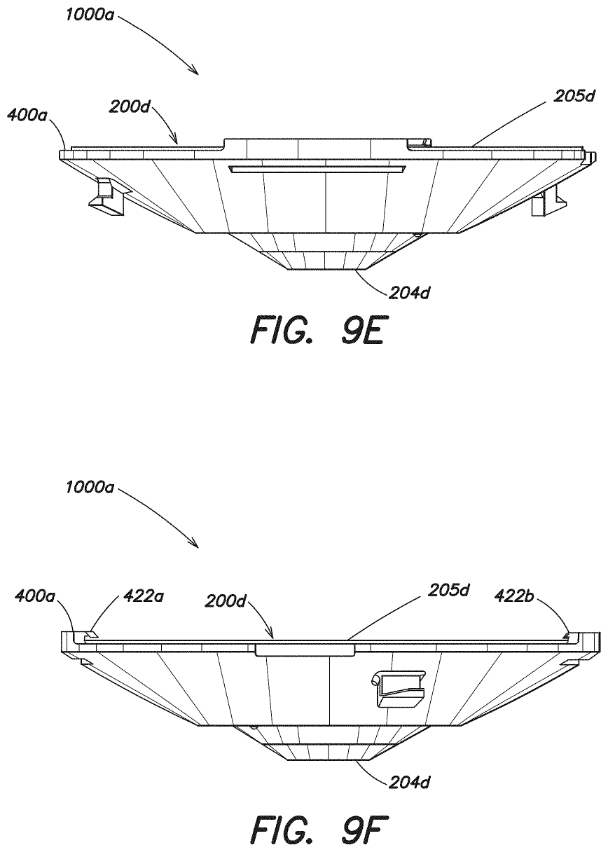

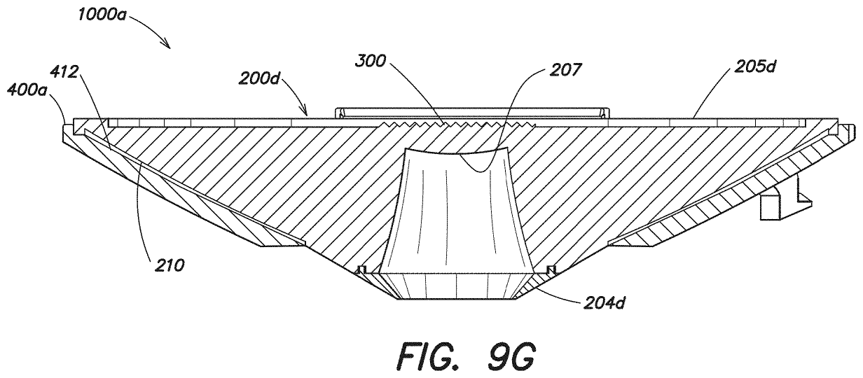

FIGS. 9A-9G show several views of an exemplary optical assembly 1000a with a hybrid optic 200d that includes a glare control diffuser 300a. As shown, the hybrid optic 200d may include a folded optical element 205d and a reflector element 204d similar in design to the folded optical element 205c and the reflector element 204c, respectively. In this implementation, however, the folded optical element 205d may include the glare control diffuser 300a integrated onto the output surface 214 and located proximate to the core output surface 207 of the hollow core 202.

As shown, the optical assembly 1000a may also include an optic holder 400a into which the hybrid optic 200d is mounted in order provide an interface for the hybrid optic 200d to be installed into a lighting system. In particular, the optic holder 400a may be structured to physically contact only the optical dead zones of the hybrid optic 200d, such as the lip 230 or the base 220 so that the optically active surfaces of the hybrid optic 200d (e.g., the reflective surface 260, the hollow core 202, the reflective outer surface 210, and the output surface 214) are not affected due to unwanted contact with the optic holder 400a or other components of the lighting system.

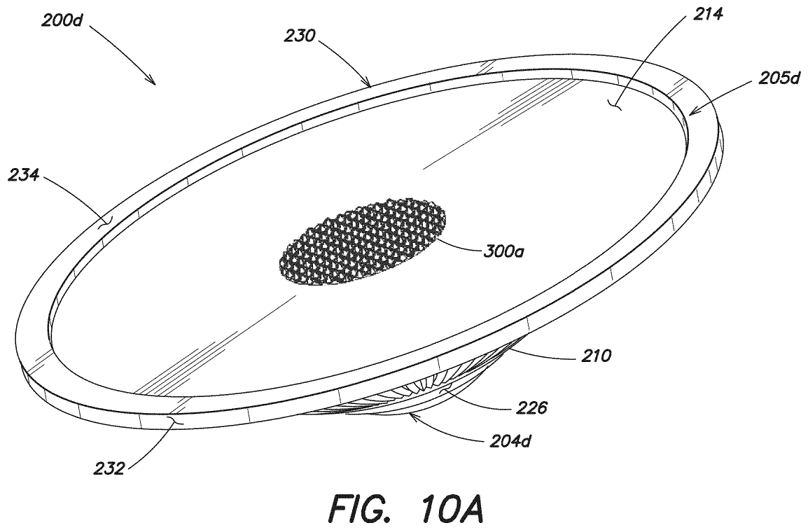

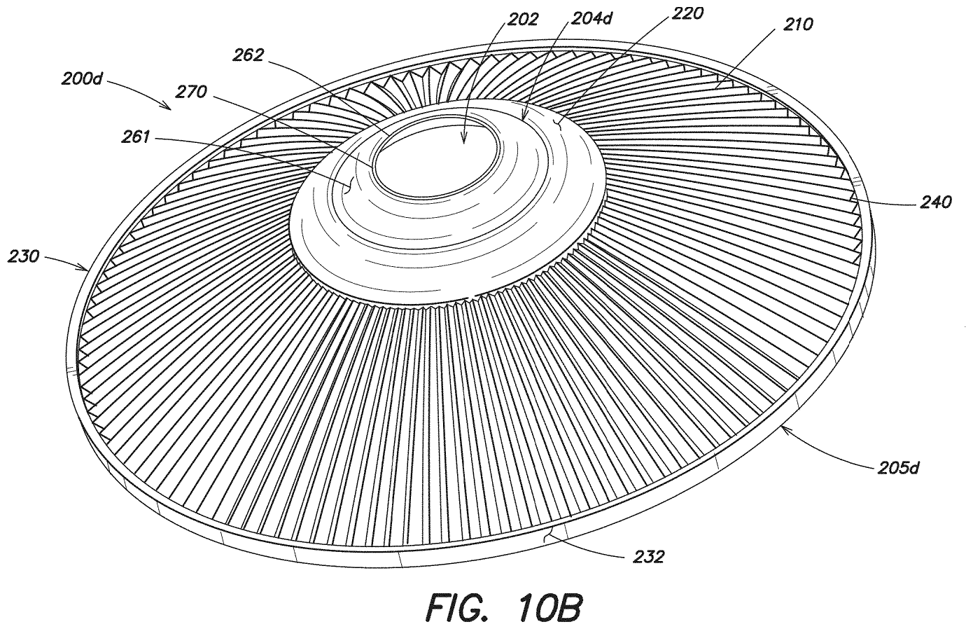

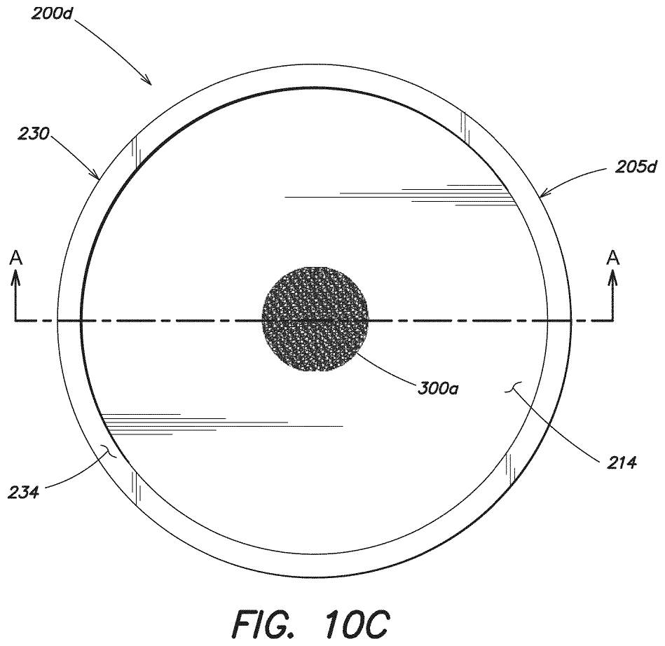

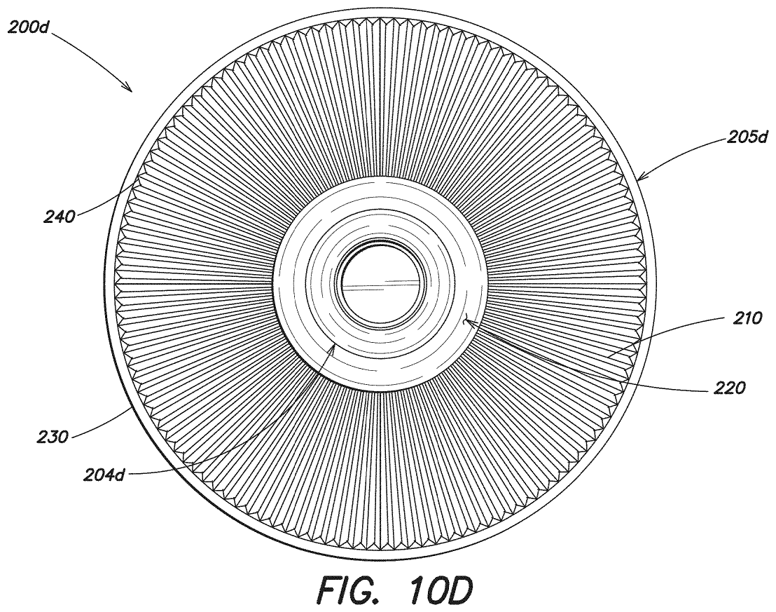

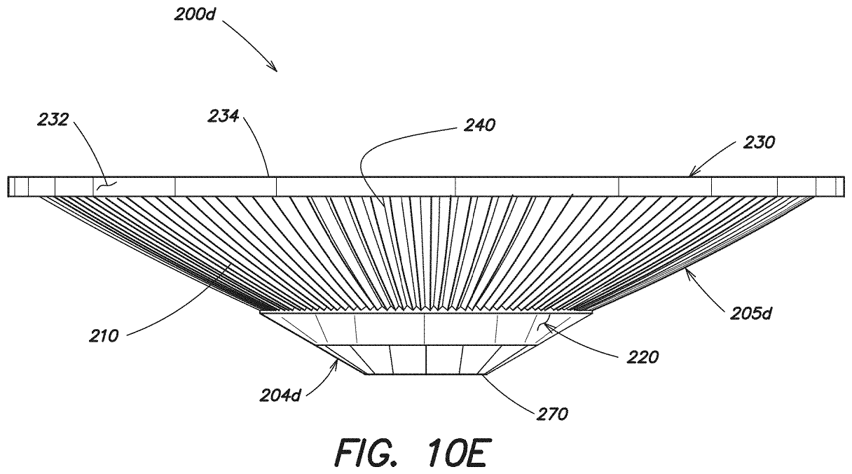

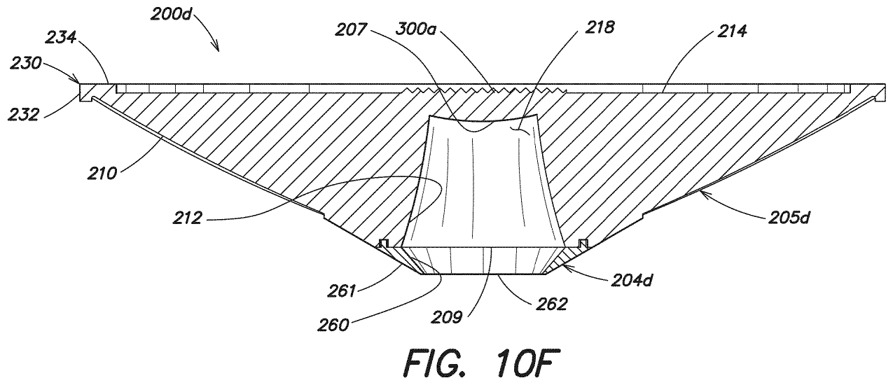

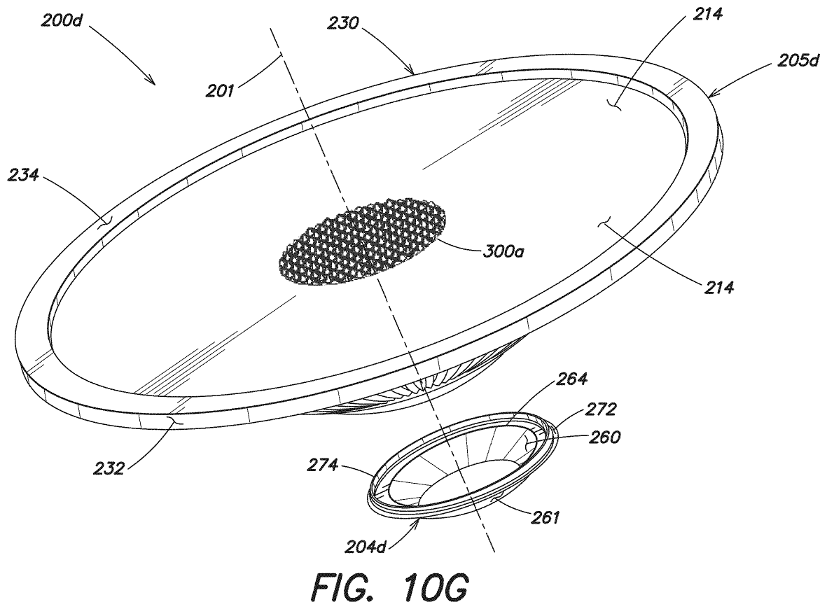

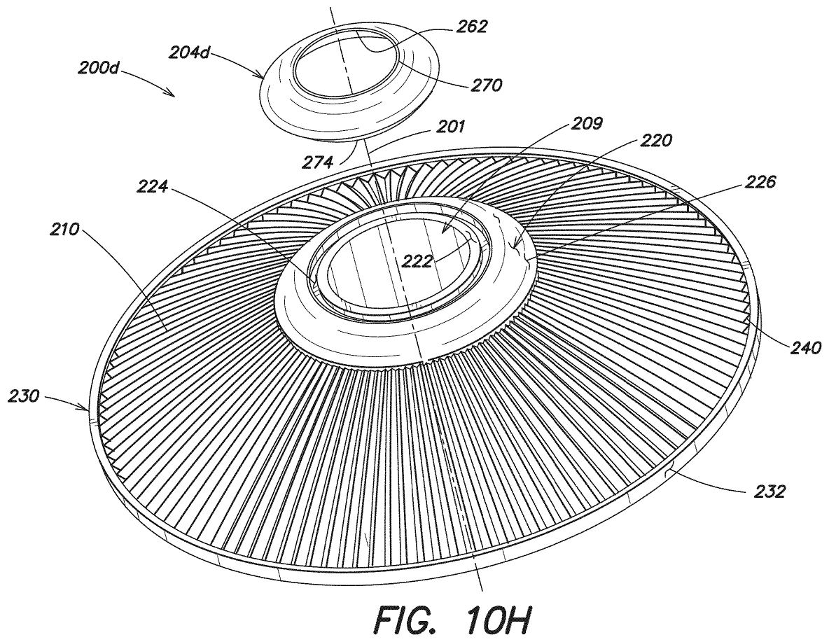

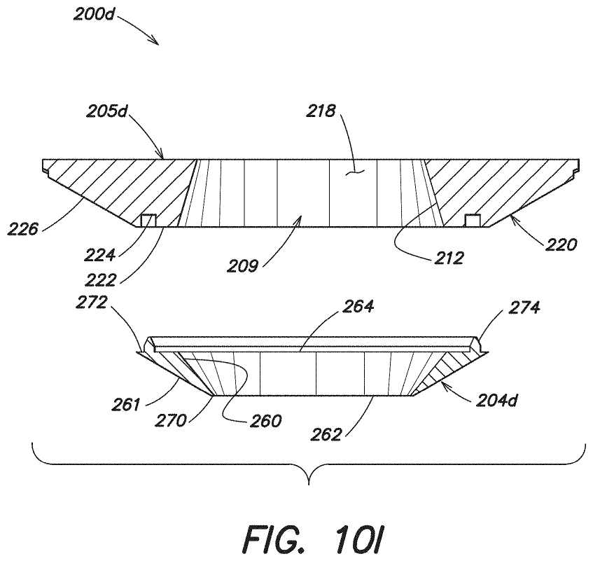

FIGS. 10A-10I show several views of the hybrid optic 200d in the optical assembly 1000a where the glare control diffuser 300a is integrated into the folded optical element 205d. As shown, the hybrid optic 200d includes the hollow core 202, the base 220, the reflective outer surface 210 with multiple prisms 240, an output surface, and a lip 230 disposed along the periphery of the output surface 214. As before, the folded optical element 205d and the reflector element 204d may be axisymmetric about an optical axis 201. The hollow core 202 may include a sidewall 212 with an aspheric profile that defines the core input opening 209 and the core output surface 207 may share an edge with the sidewall 212. The core output surface 207 may also have curvature.

The reflective outer surface 210 may include multiple V-shaped prisms 240 aligned radially with respect to the optical axis 201 to reflect incident light via TIR. The output surface 214 may be substantially flat. The lip 230 may separate the output surface 214 from the reflective outer surface 210 and include surfaces 234 and 232 to abut portions of the optic holder 400a. Furthermore, the surface 234 may be offset from the output surface 214 to prevent unwanted contact between the optic holder 400a and the output surface 214, which may otherwise affect the light guiding properties of the output surface 214 (e.g., reflection via TIR, transmission). The base 220 may be disposed between the reflective outer surface 210 and the core input opening 209. Specifically, the base 220 may include a surface 222 that shares an edge with the sidewall 212 defining the core input opening 209. The base 220 may also include a surface 226 disposed along a portion of the exterior surface, which offsets the reflective outer surface 210.

The reflector element 204d may include a sidewall 261 defining an input opening 262, an output opening 264, and a reflective surface 260. As before, the reflector element 204d may include a surface 270 to contact a light source 104 or a support structure supporting the light source 104. The reflector element 204d may also include a surface 272 to abut the surface 222 of the folded optical element 205d. As shown, the reflector element 204d may include a nipple 274, which mechanically engages a slot 224 on the surface 222.

The primary difference between the hybrid optic 200d and the hybrid optic 200c is the inclusion of the glare control diffuser 300a. The glare control diffuser 300a may function similar to a textured surface in that incident light on the glare control diffuser 300a may be dispersed along multiple directions when the light is transmitted through the surface. In other words, the glare control diffuser 300a may make the spatial and/or angular intensity of the portion of light in the first light ray bundle more uniform. In this manner, the spatial and/or angular distribution of light may be substantially smoother compared to a hybrid optic without a glare control diffuser while still maintaining the enhancement to the light coupling efficiency enabled by the hybrid optic 200d supporting multiple optic paths to couple light from the light source 104.

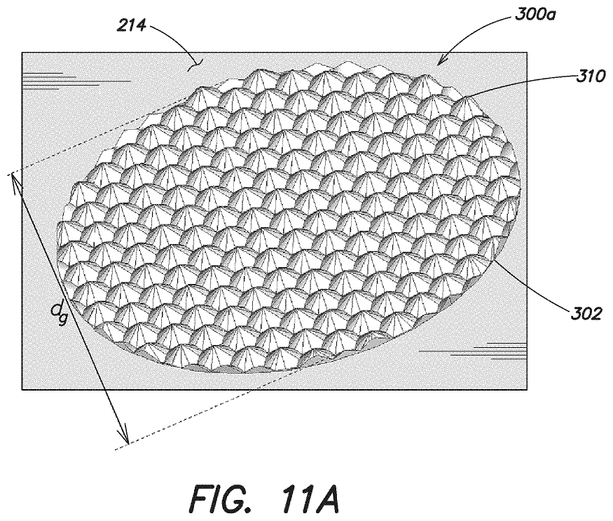

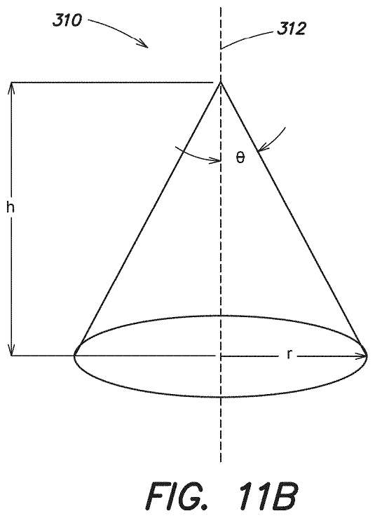

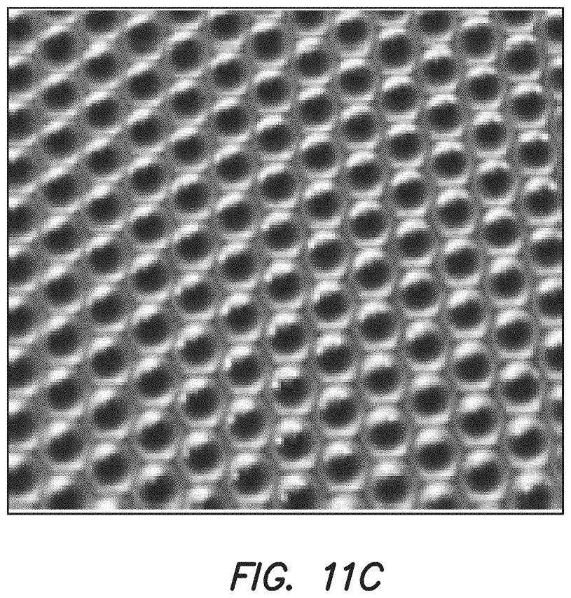

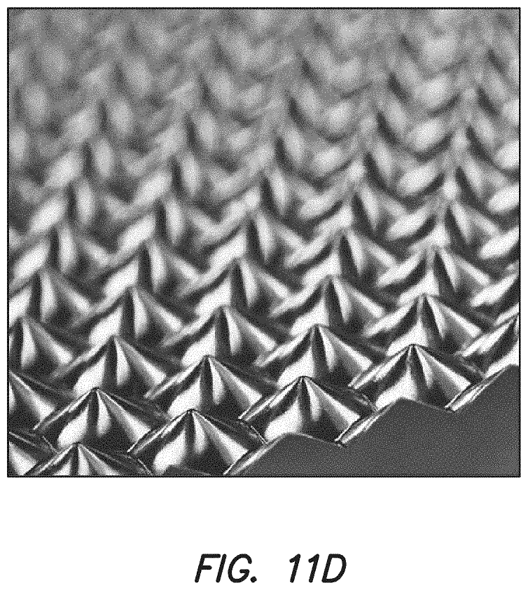

FIG. 11A shows a magnified view of the glare control diffuser 300a integrated onto the output surface 214 of the folded optical element 205d. As shown, the glare control diffuser 300a may be shaped and positioned to be axisymmetric about the optical axis 201. In some implementations, the glare control diffuser 300a may have n-fold rotational symmetry about the optical axis 201. The glare control diffuser 300a may include an array of prisms 310 that are terminated by an edge 302. In some implementations, the edge 302 may be circular in shape as shown in FIG. 11A. However, it should be appreciated in other implementations, the edge 302 may be polygonal in shape (e.g., a triangle, a square, a hexagon, an octagon).

In some implementations, the glare control diffuser 300a may have a characteristic width (e.g., a diameter if the edge 302 is circular) that is larger than the characteristic width of the core output surface 207 to ensure light from the first light ray bundle intersects the glare control diffuser 300a. The characteristic width of the glare control diffuser 300a, however, may remain sufficiently small such that light from the second light ray bundle does not intersect the glare control diffuser 300a, but is instead reflected by the output surface 214. In some implementations, the glare control diffuser 300a may have a characteristic width (e.g., a diameter if the edge 302 is circular) that is about 14 mm.

The prisms 310 in the glare control diffuser 300a may have various geometries including, but not limited to a pyramid (with a polygonal base), a hemisphere, a cone, a polyhedron and any combinations of the foregoing. For example, the prisms 310 shown in FIG. 11A may be shaped as a pyramid with a hexagonal base and a rounded side. In another example, FIG. 11B shows an illustration of a single prism 310 shaped as a cone.

As shown, the prism 310 may be characterized by a radius, r, of a circular base, a height, h, and an angle, Θ, defined between a side of the prism 310 and a center axis 312 that intersects the vertex and the center of the base of the prism 310. In some implementations, the angle, Θ, may be chosen to reflect a portion of the light incident on the prism 310 back into the body of the folded optical element 205d (e.g., towards the hollow core 202 or the reflective outer surface 210) in order reduce the intensity of light exiting the hybrid optic 200d through the core output surface 207. For instance, the prism 310 may be rotationally symmetric about the center axis 312 and the angle, Θ, may be about 45 degrees such that light that is normally incident on the prism 310 is reflected. More generally, the angle, Θ, may range between about 30 degrees and about 75 degrees. In some implementations, the prism 310 may have a height of about 0.5 mm.

In some implementations, the dimensions of the glare control diffuser 300a may be scaled with other components of the hybrid optic 200d, such as the folded optical element 205d. For example, the characteristic width of the glare control diffuser 300a may be reduced (or increased) based on the size of the folded optical element 205d. In this manner, the glare control diffuser 300a may only disperse the portion of the light that is refracted by the core output surface 207. Said in another way, the portion of the light refracted by the sidewall 212 of the hollow core 202 does not interact with the glare control diffuser 300a regardless of the overall size of the folded optical element 205d.

In some implementations, the prisms 310 in the glare control diffuser 300a may be substantially identical with one another, thus forming a periodic array. In some implementations, the shape and/or dimensions of the prisms 310 may vary spatially. For example, the glare control diffuser 300a may have larger sized prisms 310 (or smaller sized prisms 310) disposed closer to the edge 302 and smaller sized prisms 310 (or larger sized prisms 310) located near the center. In some implementations, the prisms 310 may vary in shape and size to disperse light according to a desired distribution (e.g., a smooth, uniform spatial and/or angular distribution, a distribution with a desired pattern).

In some implementations, the prisms 310 may also be arranged to form an uninterrupted array (i.e., an array of prisms with a 100% fill factor). For example, the prisms 310 shown in FIG. 11A may be arranged to form a honeycomb structure (e.g., the prisms 310 are positioned along a hexagonal lattice) due to the pyramidal shape of each prism 310. FIGS. 11C and 11D show another example of a hexagonal array of conical prisms. More generally, the arrangement of the prisms 310 may depend on the geometry of the prism 310 and, hence, is not limited to a honeycomb structure. Other arrangements of the prism 310 are possible including, but not limited to a square lattice of prims 310 and a triangular lattice of prisms 310.

In some implementations, the glare control diffuser may be integrated into the folded optical element (i.e., the glare control diffuser 300a in the folded optical element 205d) to simplify assembly. The integration of the glare control diffuser may also reduce the number of interfaces between the folded optical element and the glare control diffuser, which may otherwise give rise to unwanted reflections due, for example, to small air gaps formed between the glare control diffuser 300a and the folded optical element 205d. As shown, the glare control diffuser 300a may be a structured surface formed on the output surface 214 proximate to the core output surface 207 of the hollow core 202. In some implementations, the glare control diffuser 300a may be formed onto the output surface 214 during fabrication of the folded optical element 205d (e.g., a mold of the folded optical element 205d includes the features of the glare control diffuser 300a) or post-fabrication (e.g., the folded optical element 205d is machined or etched to form the glare control diffuser 300a onto the lens output surface 214).

It should be appreciated, however, that in some implementations, it may be beneficial for the glare control diffuser to be a separate component that is attached to the folded optical element. For example, the manufacture of the folded optical element may be simpler due to fewer constraints imposed by the fabrication of the prisms 310 of the glare control diffuser 300a (e.g., the prisms 310 may impose more stringent tolerances on the folded optical element). This, in turn, means a separate glare control diffuser may be manufactured with more complex geometries and with greater precision (e.g., narrower tolerances). When the glare control diffuser is provided as a separate component, the prisms may be formed onto a substrate. In some implementations, the substrate may have a height of about 2.5 mm.

In some implementations, the glare control diffuser may be formed from an off the shelf component that is cut into the desired shape prior to attachment to the folded optical element. For example, the glare control diffuser may be formed from a sheet/film of prisms where the sheet/film is cut into a circular shape. Examples of an off the shelf prismatic sheet/film include a Jungbecker Acrylite Conical De-Glaring Prism. The glare control diffuser may be coupled to the folded optical element using various methods including, but not limited to bonding with an adhesive and ultrasonic welding. In implementations where the glare control diffuser is bonded to the folded optical element, the adhesive may have a refractive index similar to or, in some instances, the same as the folded optical element and the glare control diffuser.

In some implementations, the glare control diffuser may be formed from the same material as the folded optical element (e.g., the glare control diffuser 300a). More generally, the glare control diffuser may be formed from different materials (e.g., various hard plastics, glasses, and ceramics) depending on the desired operating wavelength range and refractive index including, but not limited to polycarbonate, acrylic polymer, cyclo-olefin polymer (Zeonex), polystyrene, silicate-based glasses, calcium fluoride, magnesium fluoride, silicon, germanium, or zinc selenide. The refractive index of the material may also be further modified by doping or introducing porosity into the material.

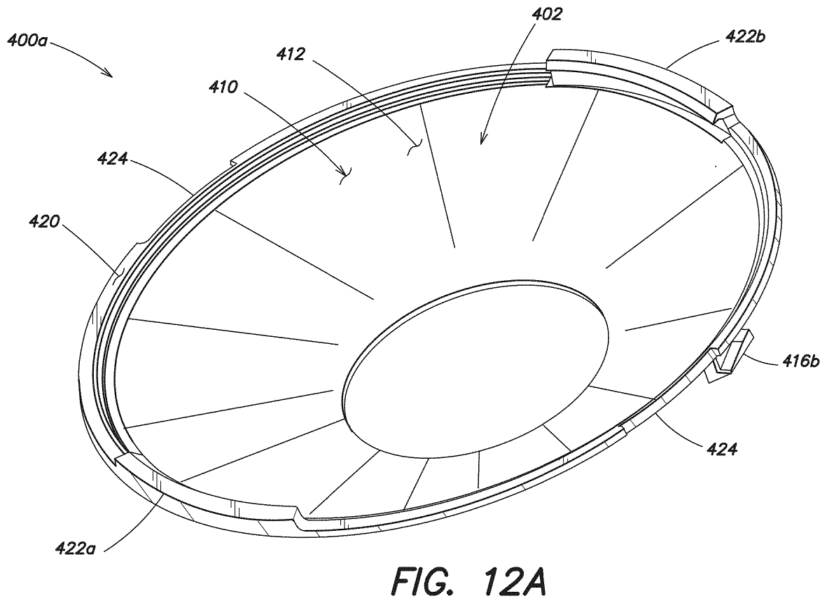

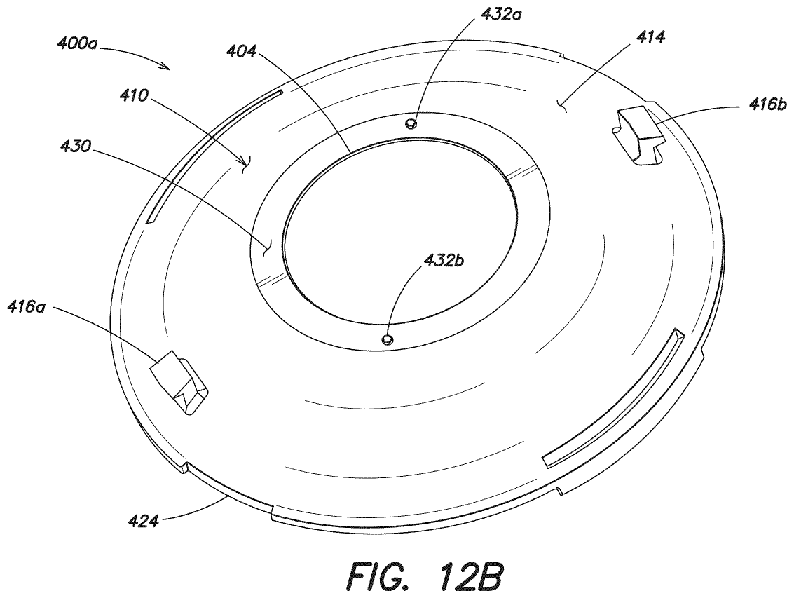

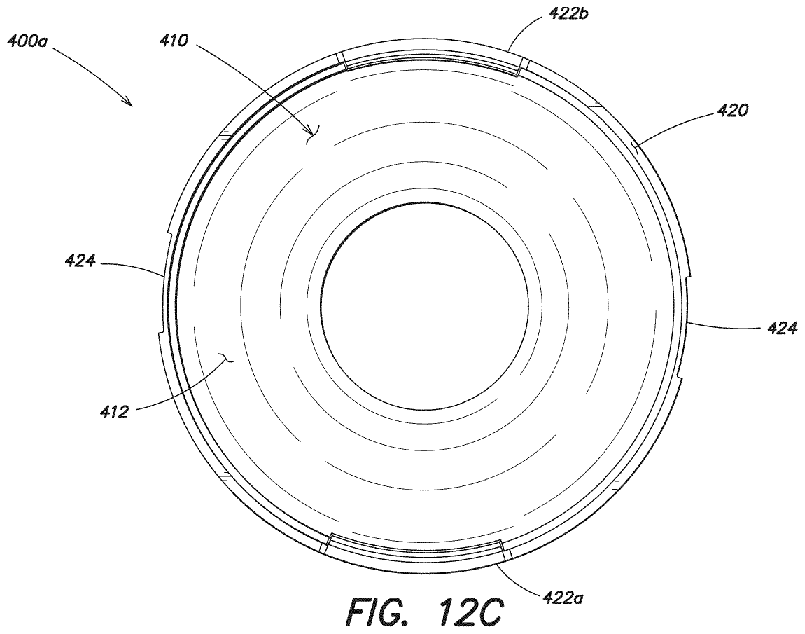

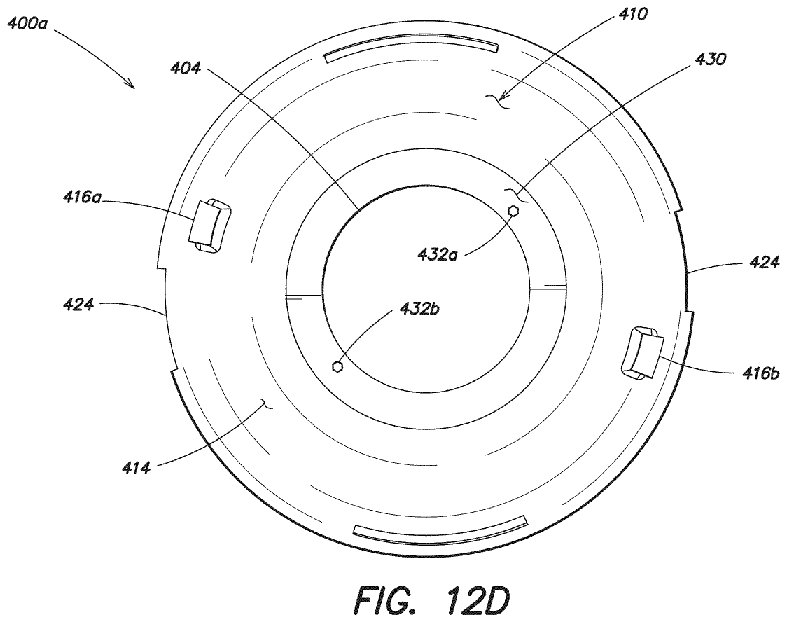

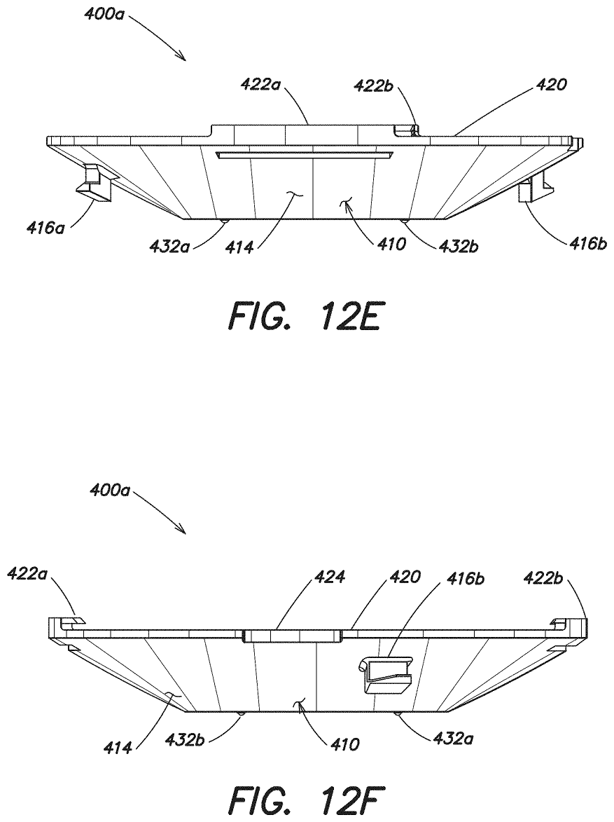

FIGS. 12A-12F show several views of the optic holder 400a, which provides an interface to mount the hybrid optic 200d to a lighting system. As shown, the optic holder 400a may include a sidewall 410 having a ridge 420 defining a first opening 402 and a base 430 defining a second opening 404. In the optical assembly 1000a, the ridge 420 is used, in part, to support the hybrid optic 200d via the lip 230 of the folded optical element 205d. The base 430 is disposed towards the reflector element 204d and terminates near the location where the surface 226 of the base 220 joins the reflective outer surface 210 of the folded optical element 205d. As shown, the sidewall 410 may be shaped to conform with the shape of the folded optical element 205d. In this manner, the optic holder 400a may substantially surround the reflective outer surface of the folded optical element 205d. In some implementations, the optic holder 400a may not contact the reflector element 204d.

FIG. 9G further shows the interior surface 412 of the sidewall 410 may be offset from the reflective outer surface 410. In other words, the optic holder 400a may be shaped such that the interior surface 412 does not physically contact the reflective outer surface 210 and, hence, does not affect the reflective properties of the prisms 240 in the reflective outer surface 210. Instead, the optic holder 400a may only contact the optical dead zones (e.g., the lip 230, the base 220) of the folded optical element 205d.

In some implementations, the interior surface 412 may also be configured to be reflective. For example, a portion of the light propagating through the hybrid optic 200d may exit the hybrid optic 200d through a surface different from the output surface 214, such as the reflective outer surface 210 or the surface 226 of the base 220, due to stray light scattering within the hybrid optic 200a. If the optic holder 400a and, in particular, the interior surface 412 is reflective, this portion of the light may be redirected back into the hybrid optic 200d and subsequently coupled out through the output surface 214 as originally intended. In this manner, the optic holder 400a may recycle light that would otherwise be lost, thus preserving the light coupling efficiency of the hybrid optic 200d.

In some implementations, the optic holder 400a and, in particular, the interior surface 412 may have a reflectivity of at least about 75%. In general, the optic holder 400a may be diffusely and/or specularly reflective. In some implementations, the optic holder 400a may be formed from a reflective material, such as a white colored plastic (e.g., Spectralon®). In some implementations, the optic holder 400a may be coated with a reflective material (e.g., a metal, a reflective polymer, a Bragg mirror).

The optic holder 400a may include several features to mechanically interface the hybrid optic 200d to a lighting system. First, the ridge 420 may include snap-fit connectors 422a and 422b to couple the hybrid optic 200d to the optic holder 400a. Specifically, FIGS. 9F and 9G show the snap-fit connectors 422a and 422b may couple to the lip 230 of the folded optical element 205d. In some implementations, the snap-fit connectors 422a and 422b may be disposed diametrically opposite one another along the ridge 420. In some implementations, the ridge 420 may further include notches 424 disposed along the periphery to provide clearance for other components in the lighting system (e.g., a snap-fit connector, a sidewall of a housing).

Second, the optic holder 400a may include several mounting features disposed, in part, along the base 430 and an exterior surface 414 of the sidewall 410. For example, FIG. 12B shows the optic holder 400a may include a pair of male twist and lock connectors 416a and 416b (e.g., protruding latch structures), which are configured to engage a corresponding female twist and lock connectors in, for example, a housing for a lighting module. The optic holder 400a may further include registration features 432a and 432b disposed on the base 430 to align and position the optical assembly 1000a to the light system and, in particular, a light source 104 in the lighting system. In some implementations, the optic holder may include additional mounting features to couple the optical assembly to a lighting system including, but not limited to snap-fit connectors, openings for screw fasteners, and press-fit connectors.

In some implementations, the exterior surface 414 of the optic holder 400a may also be shaped based on the shape of a cavity into which the optical assembly 1000a is installed. For example, the lighting system may include a housing a with a conical cavity. The exterior surface 414 may be similarly conical in order to provide a large surface area onto which the optical assembly 1000a is supported in the lighting system after installation.

In some implementations, some of the dimensions of the optic holder 400a may be scaled together with the hybrid optic 200d. For example, the dimensions of the sidewall 410 may be scaled such that the interior surface 412 only covers the reflective outer surface 210 of the folded optical element 205d. In another example, the dimensions of the ridge 420 may be scaled to ensure the snap-fit connectors 422a and 422b couple only to the lip 230 of the folded optical element 205d. However, it should be appreciated some features and/or dimensions of the optic holder 400a may be subject to other constraints. For example, the position and alignment of the twist and lock connectors 416a and 416b and/or the registration features 432a and 432b may depend on the housing into which the optical assembly 400a is being installed.

The optic holder 400a may be formed from various polymers including, but not limited to polyethylene, polypropylene, polycarbonate, polyethylene terephthalate, polyvinyl chloride, polystyrene, and Spectralon®. The optic holder 400a may be fabricated using various techniques including, but not limited to injection molding, blow bolding, 3D printing, and machining.

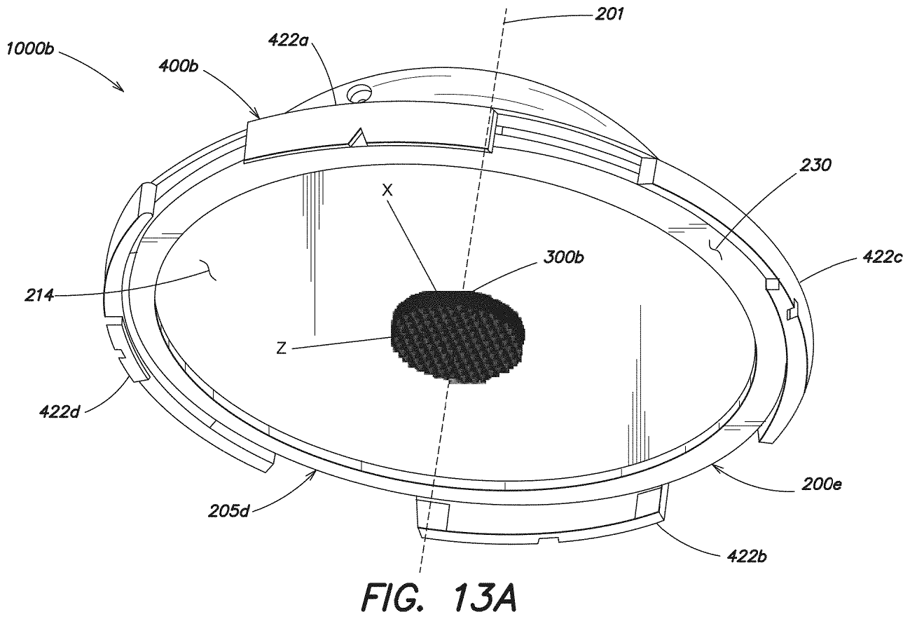

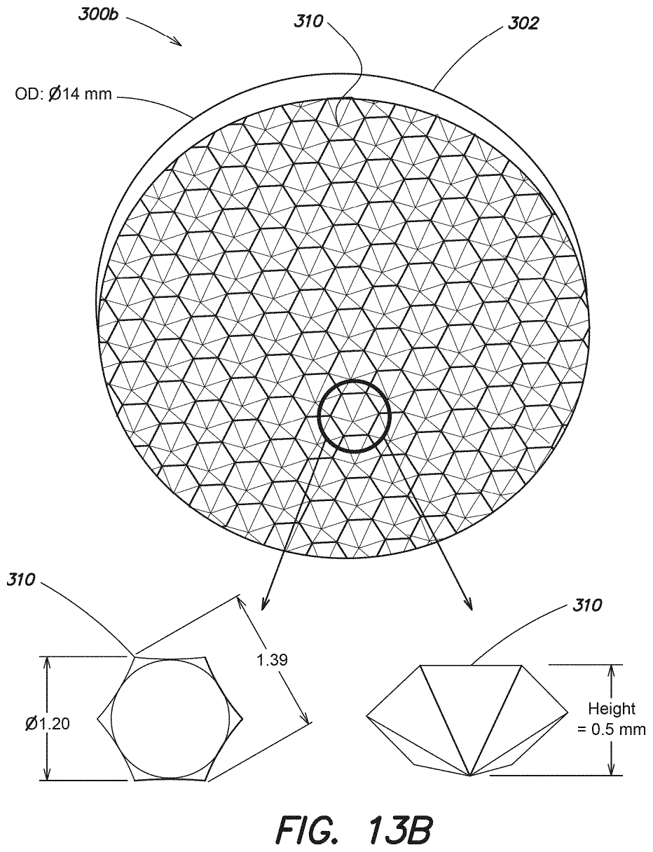

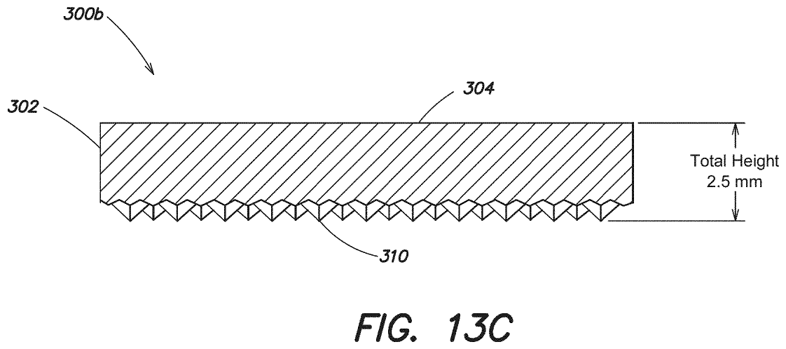

FIGS. 13A-13C show another exemplary optical assembly 1000b with a separate glare control diffuser 300b that is attached to the folded optical element 205d in the hybrid optic 200e. The folded optical element 205d and the reflector element 204d may be the same as in the optical assembly 1000a. As shown, the glare control diffuser 300b may be circular in shape and centered about the optical axis 201 of the hybrid optic 200d. FIGS. 13B and 13C show several views of the glare control diffuser 300b.

Additionally, the optic holder 400b may be a variant of the optic holder 400a. As before, the optic holder 400b may substantially surround the reflective outer surface 210 of the folded optical element 205d while avoiding physical contact with the reflective outer surface 210 and the other optically active surfaces. Compared to the optic holder 400a, the optic holder 400b may include four snap-fit connectors 422a-422d to provide additional mechanical support to the hybrid optic 200e.

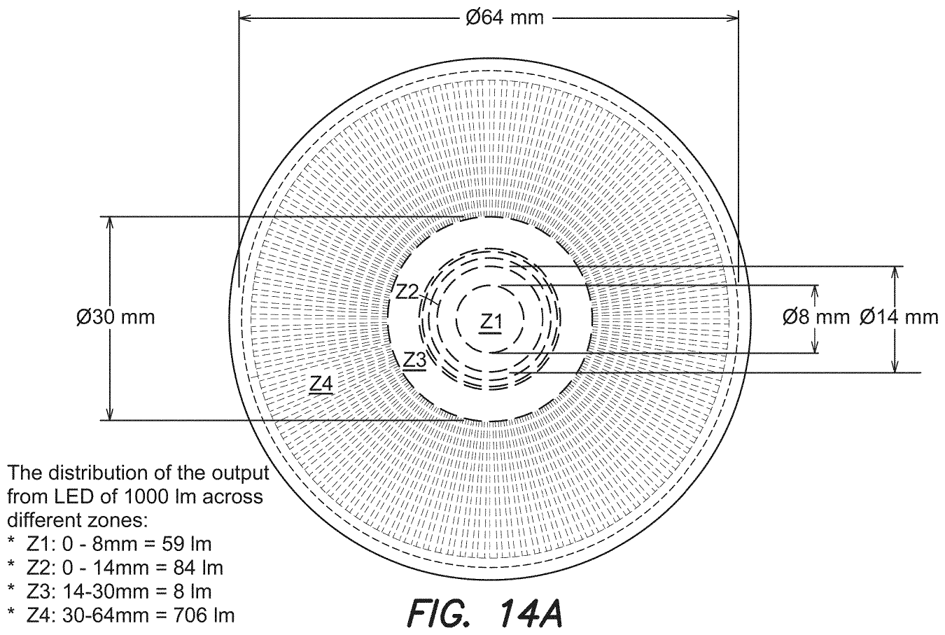

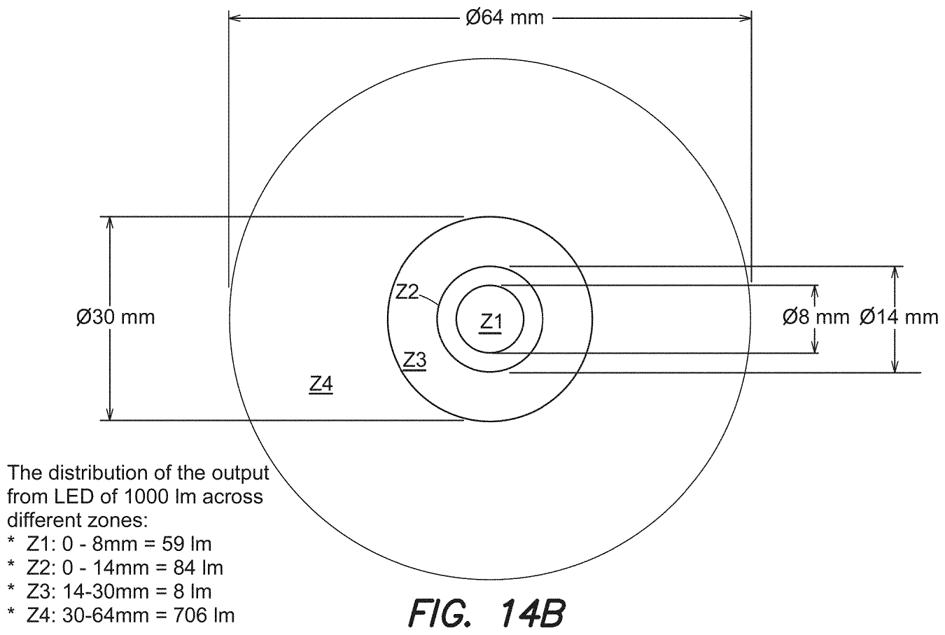

In order to demonstrate the benefits of incorporating a glare control diffuser into the hybrid optic, the following describes ray tracing simulations comparing a hybrid optic with the glare control diffuser and another hybrid optic without the glare control diffuser. FIGS. 14A and 14B show a top view and a bottom view, respectively, of an exemplary model of the hybrid optic used for the ray tracing simulations. As shown, the model of the hybrid optic may have a similar shape and dimensions as the hybrid optics 200a-200d, previously described. For instance, the outer diameter of the hybrid optic may be 64 mm, the diameter where the base and the reflective outer surface are joined is 30 mm, the diameter of the core input opening is 14 mm, and the diameter of the core output surface is 8 mm. Additionally, none of the surfaces of the hybrid optic are textured. The amount of light exiting the hybrid optic via different optical paths may be evaluated based on the amount of light incident on the different surfaces of the hybrid optic.

To simulate real-world conditions, the hybrid optic may be disposed inside an exemplary model of a lighting fixture with a trim. A light source may be modeled by generating representative light rays emitted from the surface of the light source based on the spatial and/or angular distribution of light associated with the light source. For example, the location and emission angle may be sampled from a known spatial and angular distribution. Thus, the light source may be represented accurately so long as a sufficient number of light rays are generated to sample the spatial and/or angular distribution.

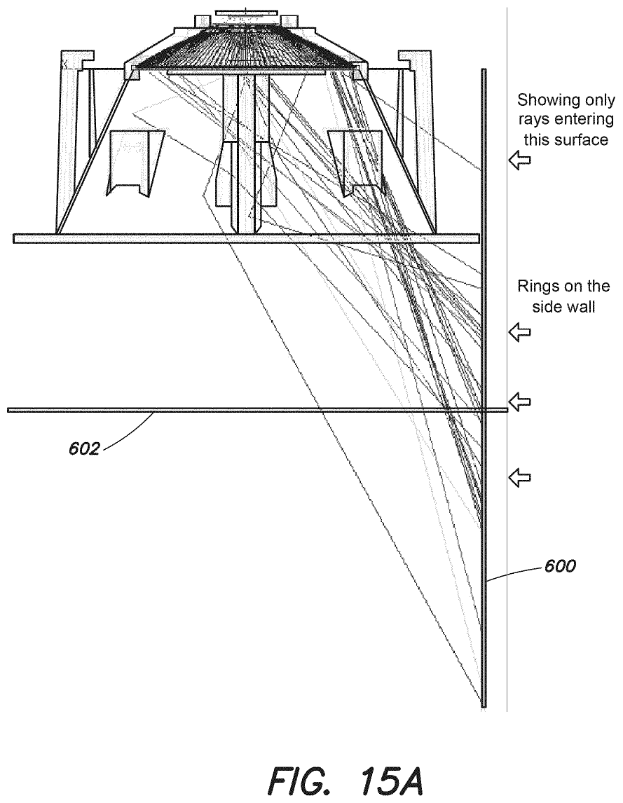

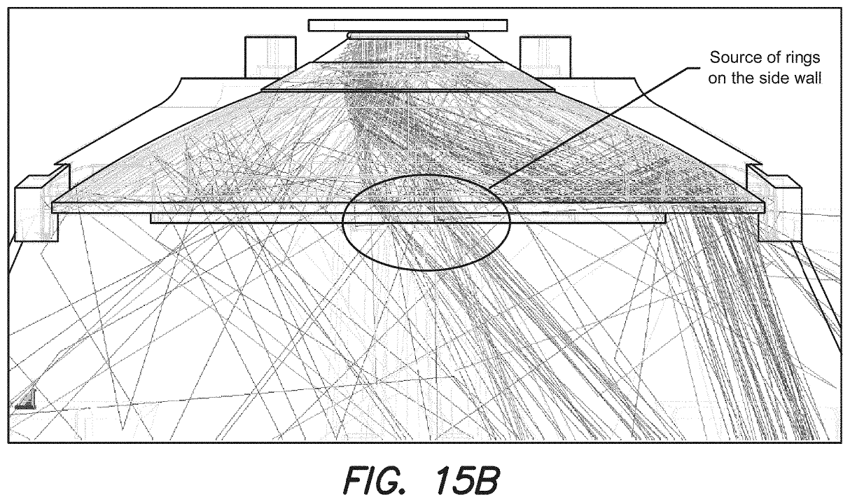

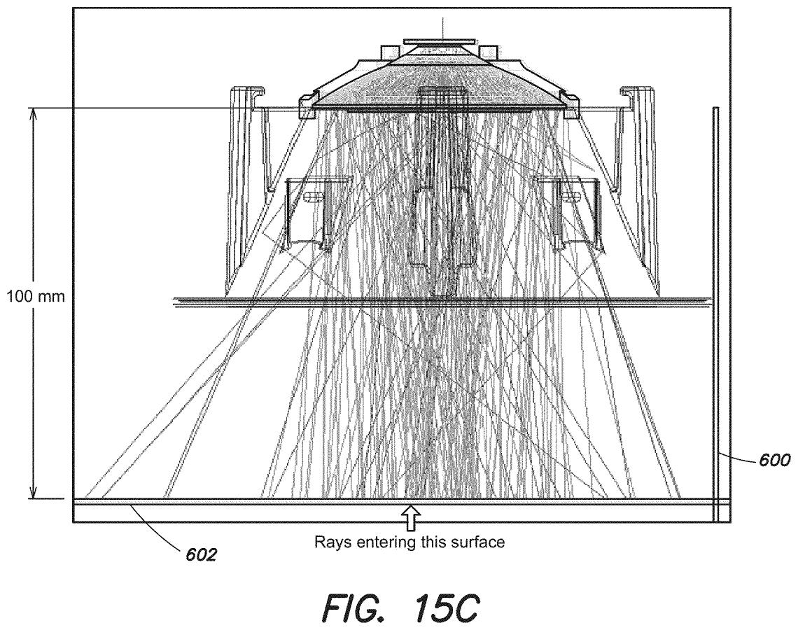

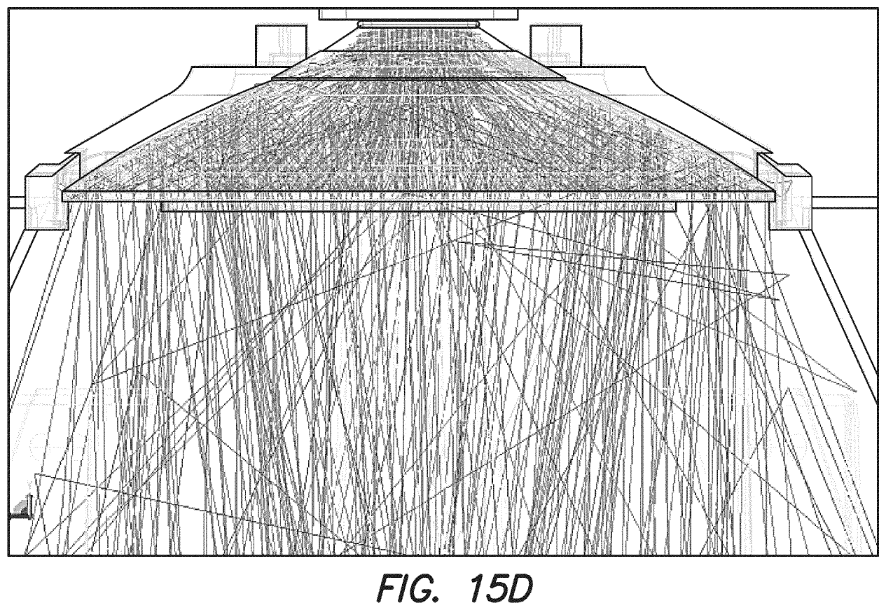

FIGS. 15A-15D show several views of an exemplary ray trace of the hybrid optic without a glare control diffuser. FIG. 15A shows a side view of the ray trace where the light rays shown correspond to light rays that intersect a plane 600 representing a wall disposed near the lighting fixture. As shown, the light rays are concentrated at several discrete locations along the plane 600 resulting in the formation of rings of higher intensity light, which in turn produces a multiple scalloping effect. FIG. 15B shows a magnified view of the ray trace near the folded optical element. As shown, the formation of the structured light may be attributed, in part, by a concentration of light exiting the hybrid optic through the core optic boundary. For reference, FIGS. 15C and 15D show corresponding ray traces where the light rays shown correspond to light rays that intersect a plane 602 located 150 mm below the hybrid optic 200. The results shown in FIGS. 15C and 15D may be used to evaluate the spatial and/or angular distribution of light exiting the hybrid optic.

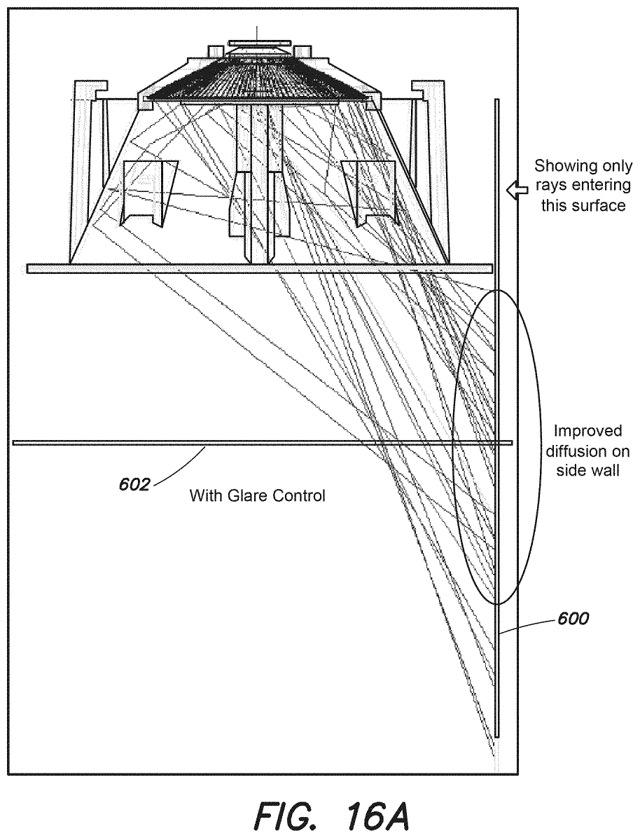

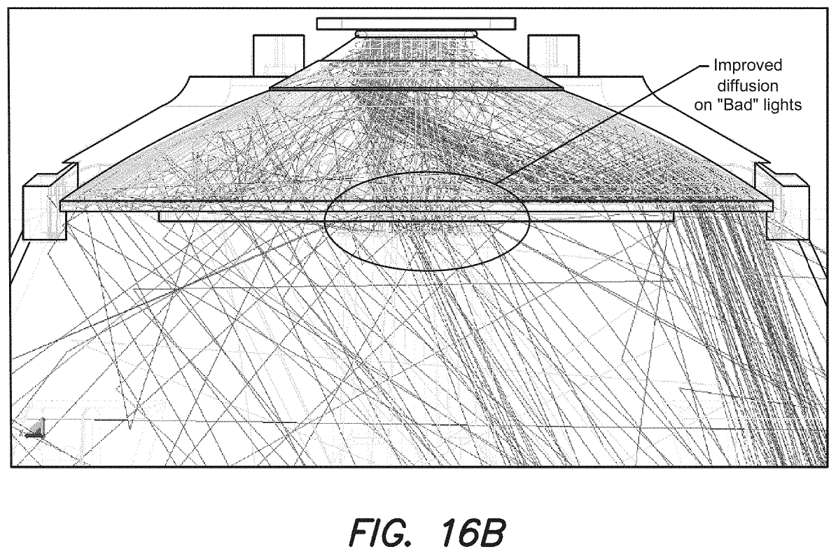

In comparison, FIGS. 16A and 16B show ray traces of a hybrid optic with a glare control diffuser attached to the output surface of the folded optical element. Similar to FIG. 15A, the ray trace of FIG. 16A shows light rays that intersect the plane 600 representing the wall. Qualitatively, FIG. 16A shows the light rays are more uniformly distributed along the plane 600 compared to FIG. 15A, which suggests the rings/scalloping observed in FIG. 15A are appreciably reduced. FIG. 16B shows a magnified view of the ray trace near the folded optical element, which shows the light rays from exiting the hybrid optic via transmission through the core output surface is distributed more evenly compared to FIG. 15B.

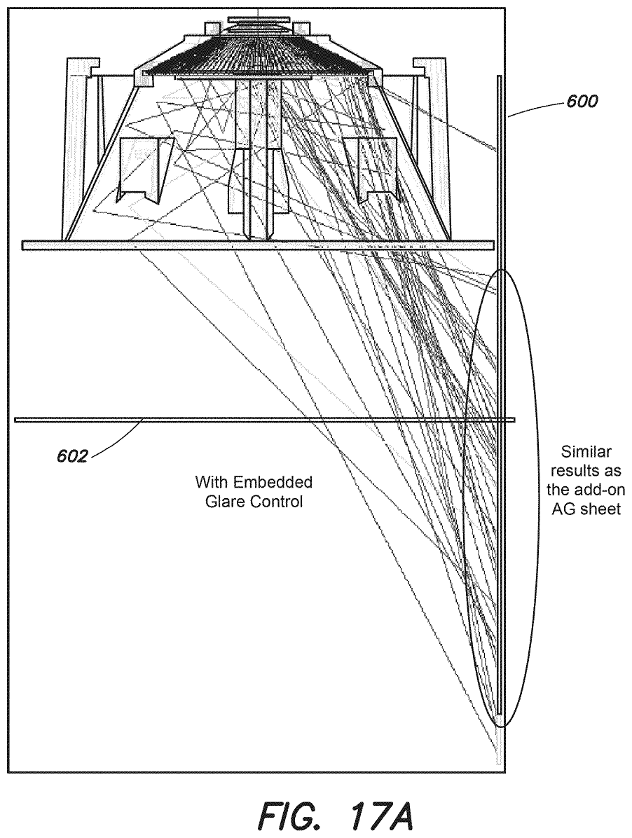

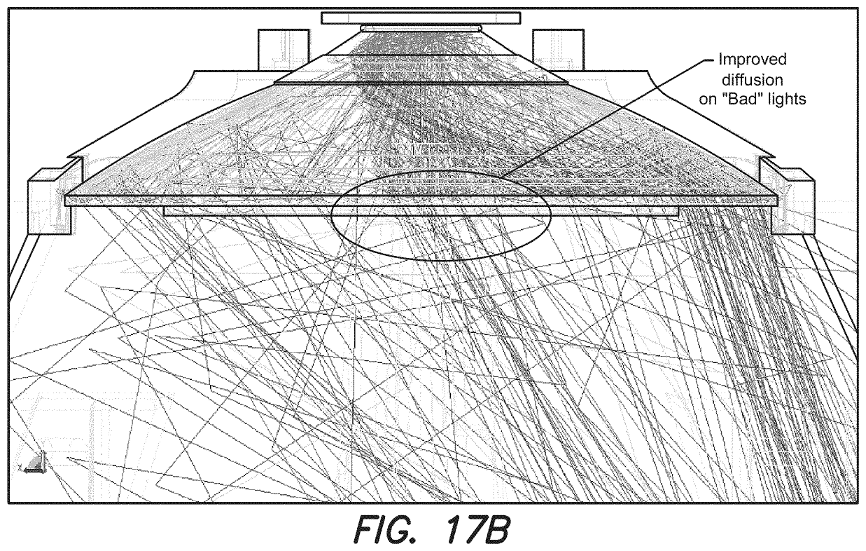

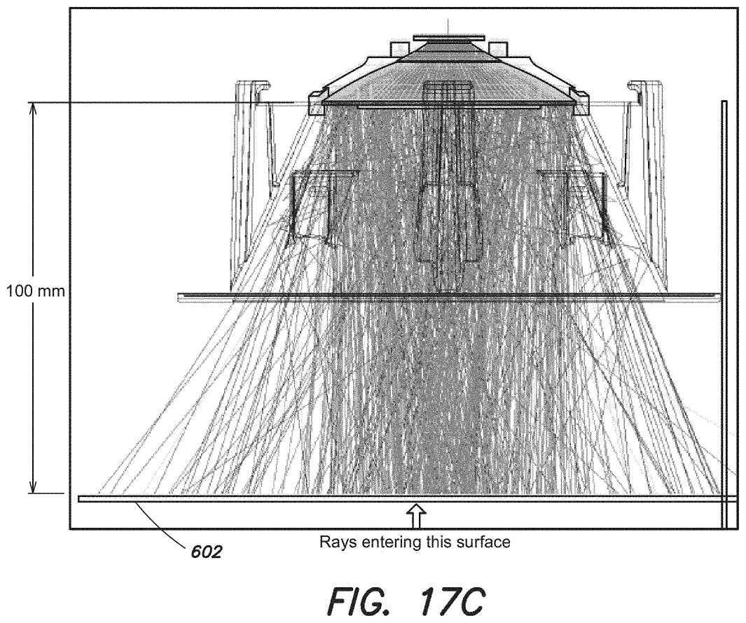

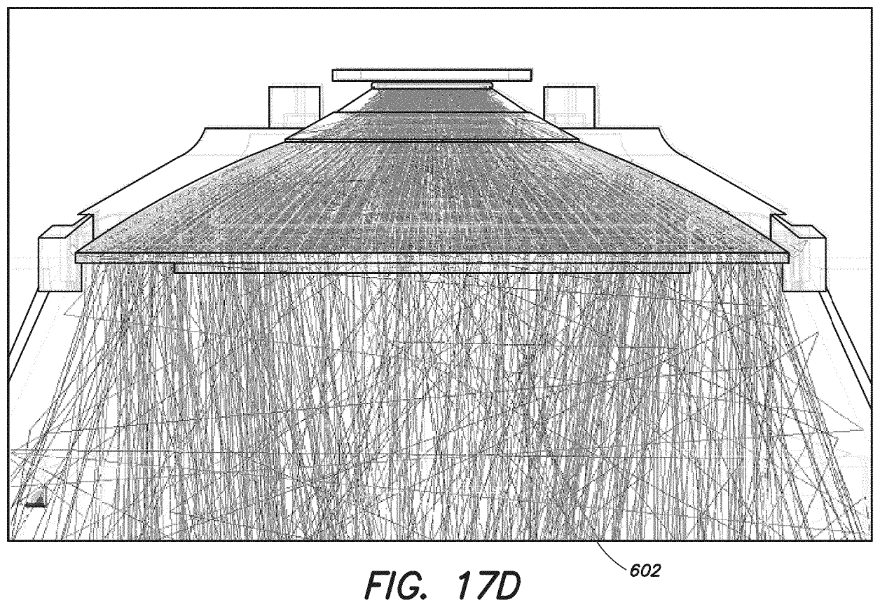

FIGS. 17A and 17B further show ray traces of a hybrid optic with an integrated glare control diffuser. Once again, the presence of the glare control diffuser results in light rays that are more evenly distributed along the plane 600. This suggests the improvements to the spatial and/or angular distribution of light is not sensitive to the manner in which the glare control diffuser is implemented into the hybrid optic (e.g., attached as a separate part to the folded optical element, formed together with the folded optical element). In other words, so long as a light dispersive structure is disposed near the core output surface of the folded optical element, the appearance of non-uniformities may be appreciably reduced. For reference, FIGS. 17C and 17D show ray traces of light rays intersecting the plane 602. As shown, the glare control diffuser does not appreciably affect the amount of light coupled out of the hybrid optic, hence, the increase in light coupling efficiency is maintained while the presence of non-uniformities in the output light is reduced.

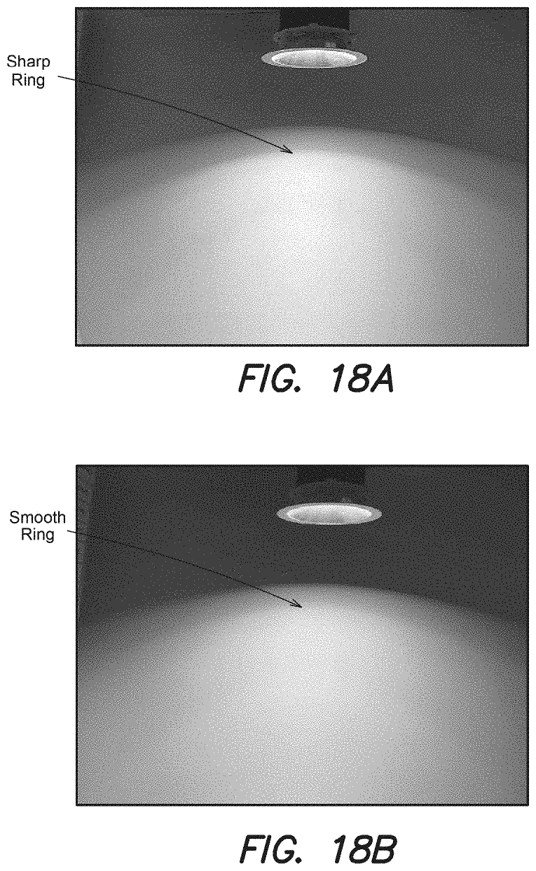

As further demonstration of the effect of the glare control diffuser on the output light, FIGS. 18A and 18B show photographs of a lighting fixture with and without the glare control diffuser, respectively. As shown, the lighting fixtures are illuminating a wall. In FIG. 18A, the light pattern on the wall exhibits a double scalloping effect where two distinct regions with different light intensities are distinguished by a sharp transition (i.e., a sharp ring). In contrast, FIG. 18B shows the inclusion of a glare control diffuser softens the appearance of the ring, resulting in a smoother gradient and, hence, a less observable double scalloping effect.

### CONCLUSION

All parameters, dimensions, materials, and configurations described herein are meant to be exemplary and the actual parameters, dimensions, materials, and/or configurations will depend upon the specific application or applications for which the inventive teachings is/are used. It is to be understood that the foregoing embodiments are presented primarily by way of example and that, within the scope of the appended claims and equivalents thereto, inventive embodiments may be practiced otherwise than as specifically described and claimed. Inventive embodiments of the present disclosure are directed to each individual feature, system, article, material, kit, and/or method described herein.

In addition, any combination of two or more such features, systems, articles, materials, kits, and/or methods, if such features, systems, articles, materials, kits, and/or methods are not mutually inconsistent, is included within the inventive scope of the present disclosure. Other substitutions, modifications, changes, and omissions may be made in the design, operating conditions and arrangement of respective elements of the exemplary implementations without departing from the scope of the present disclosure. The use of a numerical range does not preclude equivalents that fall outside the range that fulfill the same function, in the same way, to produce the same result.

Also, various inventive concepts may be embodied as one or more methods, of which at least one example has been provided. The acts performed as part of the method may in some instances be ordered in different ways. Accordingly, in some inventive implementations, respective acts of a given method may be performed in an order different than specifically illustrated, which may include performing some acts simultaneously (even if such acts are shown as sequential acts in illustrative embodiments).

All publications, patent applications, patents, and other references mentioned herein are incorporated by reference in their entirety.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03.

1. An optical element to redirect light emitted by a light source during operation of the light source, the optical element comprising:
a folded optical element, comprising:
a hollow core, comprising:
a sidewall surrounding a cavity and defining an opening through which the light enters the cavity, the sidewall refracting a first portion of the light; and
a core output surface, joined to the sidewall, to refract a second portion of the light;
an output surface from which the light exits the folded optical element, the output surface reflecting the first portion of the light before the first portion of the light exits the folded optical element; and
a reflective outer surface; and
a glare control diffuser, disposed on the output surface proximate to the core output surface, to disperse the second portion of the light.

2. The optical element of claim 1, wherein the glare control diffuser and the folded optical element are formed as a single part.

3. The optical element of claim 1, wherein the glare control diffuser is at least one of bonded to the folded optical element with an adhesive or welded to the folded optical element.

4. The optical element of claim 1, wherein the glare control diffuser comprises a plurality of prisms to disperse the light.

5. The optical element of claim 4, wherein:
each prism in the plurality of prisms of the glare control diffuser is pyramidal in shape; and
the plurality of prisms is arranged to form a honeycomb structure.

6. The optical element of claim 4, wherein:
each prism in the plurality of prisms of the glare control diffuser is at least one of conical or pyramidal in shape;
the prism comprises a side oriented at an angle relative to a center axis, the side intersecting a vertex of the prism, the center axis intersecting the vertex and a center of a base of the prism; and
the angle between the side and the center axis ranges between about 30 degrees and about 75 degrees.

7. The optical element of claim 4, wherein:
each prism in the plurality of prisms of the glare control diffuser is shaped to reflect at least a portion of the light back towards at least one of the hollow core or the reflective outer surface when the light is approximately at normal incidence to the prism.

8. The optical element of claim 1, wherein:
the glare control diffuser has an outer edge that is circular in shape; and
the outer edge has a diameter of about 14 mm.

9. The optical element of claim 1, wherein:
the glare control diffuser has a first characteristic width;
the first characteristic width is greater than a second characteristic width of the core output surface; and
the first characteristic width is sufficiently small such that the first portion of the light refracted by the sidewall of the hollow core does not interact with the glare control diffuser.

10. The optical element of claim 1, wherein:
the glare control diffuser is centered about an optical axis of the optical element; and
the glare control diffuser has n-fold rotational symmetry about the optical axis.

11. The optical element of claim 1, wherein:
the optical element has an optical axis; and
the glare control diffuser, the sidewall of the hollow core, and the core output surface of the hollow core are rotationally symmetric about the optical axis.

12. The optical element of claim 1, wherein the reflective outer surface comprises a plurality of triangular-shaped grooves forming corresponding total internal reflection prisms, the plurality of triangular-shaped grooves being radially oriented with respect to an optical axis of the optical element.

13. The optical element of claim 1, wherein the output surface is substantially flat.

14. The optical element of claim 1, wherein the folded optical element has an outer diameter ranging between about 35 mm and about 110 mm.

15. The optical element of claim 1, further comprising:
a reflector element, optically coupled to the opening of the hollow core, to receive the light emitted by the light source and reflect at least a portion of the received light.

16. The optical element of claim 15, wherein the reflector element diffusely reflects the received light.

17. The optical element of claim 15, wherein the reflector element is white in color.

18. The optical element of claim 15, wherein during operation of the light source:
a first light ray bundle passes first into the reflector element and then into the hollow core without reflection by the reflector element, is thereafter refracted by the core output surface of the hollow core, and is thereafter dispersed by the glare control diffuser;
a second light ray bundle passes first into the reflector element and then into the hollow core without reflection by the reflector element, is thereafter refracted at the sidewall of the hollow core, is thereafter reflected at the output surface of the folded optical element, is thereafter reflected at the reflective outer surface of the folded optical element, and is thereafter transmitted through the output surface of the folded optical element;
a third light ray bundle passes first into the reflector element and is reflected by the reflector element into the hollow core, is thereafter refracted by the core output surface of the hollow core, and is thereafter dispersed by the glare control diffuser; and
a fourth light ray bundle passes first into the reflector element and is reflected by the reflector element into the hollow core, is thereafter refracted at the sidewall of the hollow core, is thereafter reflected at the output surface of the folded optical element, is thereafter reflected at the reflective outer surface of the folded optical element, and is thereafter transmitted through the output surface of the folded optical element.

19. An optical assembly, comprising:
the optical element of claim 1; and
an optic holder coupled to the optical element via one or more snap-fit connectors.

20. The optical assembly of claim 19, wherein the optic holder includes a holder sidewall (410) that substantially surrounds the reflective outer surface of the folded optical element.

21. The optical assembly of claim 20, wherein:
a portion of the light exits the optical element through the reflective outer surface during operation of the light source; and
the holder sidewall includes an interior surface to reflect the portion of the light back into the optical element.

22. The optical assembly of claim 20, wherein the holder sidewall includes an interior surface having a reflectivity of at least about 75%.

23. The optical assembly of claim 20, wherein the optic holder further comprises a pair of twist and lock connectors disposed on an exterior surface of the holder sidewall.

24. The optical assembly of claim 19, wherein the optic holder does not physically contact the output surface and the reflective outer surface of the folded optical element.

25. The optical assembly of claim 19, wherein:
the folded optical element includes a lip disposed along the periphery of the output surface; and
the snap-fit connectors of the optic holder physically contact the lip of the folded optical element.

26. An optical element to redirect light emitted by a light source during operation of the light source, the optical element comprising:
a folded optical element defining an optical axis of the optical element, the folded optical element comprising:
a hollow core, comprising:
a sidewall surrounding a cavity and defining an opening through which the light enters the cavity, the sidewall refracting a first portion of the light, the sidewall having a first curved profile; and
a core output surface, joined to the sidewall, to refract a second portion of the light, the core output surface being rotationally symmetric about the optical axis;
an output surface, disposed proximate to and in concentric alignment with the core output surface, from which the light exits the folded optical element, the output surface reflecting the first portion of the light via total internal reflection (TIR) before the first portion of the light exits the folded optical element, the output surface being a substantially flat surface that intersects the optical axis;
a reflective outer surface to reflect the first portion of the light before the first portion of the light exits the folded optical element, the reflective outer surface having a second curved profile, the reflective outer surface comprising a plurality of triangular-shaped grooves forming corresponding TIR prisms, the plurality of triangular-shaped grooves being radially oriented with respect to the optical axis;
a lip, disposed along the periphery of the output surface to separate the plurality of triangular-shaped grooves of the outer reflective surface from the output surface, the lip comprising a surface that is parallel with the output surface and offset from the output surface; and
a first surface, disposed between the reflective outer surface and the opening of the hollow core, having an annular slot; and
a glare control diffuser, disposed proximate to and in concentric alignment with the core output surface, to disperse the second portion of the light, the glare control diffuser having a plurality of pyramidal prisms arranged to form a honeycomb structure and a circularly shaped outer edge, the glare control diffuser having n-fold rotational symmetry about the optical axis,
wherein:
the first curved profile of the sidewall is a first aspheric profile defined by a first relation:
$${z}^{′} = \frac{{c}^{′} {r}^{′2}}{1 + \sqrt{1 - ( 1 + {k}^{′} ) {c}^{′2} {r}^{′2}}} + {α}_{4}^{′} {r}^{′4} + {α}_{6}^{′} {r}^{′6}$$
wherein z′ is a value along a first coordinate axis perpendicular to the optical axis of the optical element, and z′ given by the first relation is a first displacement component along the first coordinate axis, from a vertex of the first aspheric profile, at a corresponding distance r′ from the first coordinate axis at which a point on the sidewall lies, and α′₄ and α′₆ are coefficients where at least one of α′₄ or α′₆ are non-zero;
the second curved profile of the reflective outer surface is a second aspheric profile defined by a second relation:
$$z = \frac{{cr}^{2}}{1 + \sqrt{1 - ( 1 + k ) {c}^{2} {r}^{2}}} + {α}_{1} {r}^{2} + {α}_{2} {r}^{4} + {α}_{3} {r}^{6} + {α}_{4} {r}^{8}$$
wherein z is a value along a second coordinate axis defined by the optical axis of the optical element, and z given by the second relation is a second displacement component along the second coordinate axis, from a vertex of the second aspheric profile, at a corresponding distance r from the second coordinate axis at which a point on the reflective outer surface lies, and α₁, α₂, α₃, α₄ are coefficients where at least one of α₂, α₃, or α₄ are non-zero;
the hollow core is defined in the folded optical element by rotating a portion of the first aspheric profile around the optical axis at a predetermined offset distance between the vertex of the first aspheric profile and the optical axis; and
at least one of the core output surface, the lip, or the first surface is textured to at least one of diffusely reflect or diffusely transmit a portion of the light.

27. The optical element of claim 26, wherein the glare control diffuser and the folded optical element are formed as a single part.

28. The optical element of claim 26, wherein the glare control diffuser is at least one of bonded to the folded optical element with an adhesive or welded to the folded optical element.

29. The optical element of claim 26, wherein:
each prism in the plurality of prisms of the glare control diffuser is at least one of conical or pyramidal in shape;
the prism comprises a side oriented at an angle relative to a center axis, the side intersecting a vertex of the prism, the center axis intersecting the vertex and a center of a base of the prism; and
the angle between the side and the center axis is about 45 degrees.

30. The optical element of claim 26, wherein the folded optical element has an outer diameter ranging between about 35 mm and about 110 mm.

31. The optical element of claim 26, further comprising:
a reflector element optically coupled to the opening of the hollow core and disposed outside the hollow core, the reflector element comprising:
a reflector sidewall defining a reflector input opening to receive the light from the light source and a reflector output opening for the received light to exit the reflector element, the reflector sidewall diffusely reflecting at least a portion of the received light, the reflector output opening being substantially similar in shape and size with the opening of the hollow core; and
a second surface, adjoining the reflector output opening and abutting the first surface of the folded optical element, having an annular nipple that is inserted into the annular slot of the folded optical element.

32. An optical assembly, comprising:
the optical element of claim 26; and
an optic holder coupled to the optical element, the optic holder comprising:
a holder sidewall defining a first holder end and a second holder end, the sidewall having a frustoconical shape, the holder sidewall substantially surrounding the reflective outer surface of the folded optical element of the optical element, the holder sidewall having an interior surface that does not physically contact the reflective outer surface of the folded optical element;
a first snap-fit connector, disposed on the first holder end, to couple to the lip of the folded optical element of the optical element; and
a second snap-fit connector, disposed on the first holder end and located diametrically opposite from the first snap-fit connector, to couple to the lip of the folded optical element of the optical element.

33. The optical assembly of claim 32, wherein the interior surface of the holder sidewall has a reflectivity of at least about 75%.

34. The optical assembly of claim 32, wherein the optic holder further comprises a pair of twist and lock connectors disposed on an exterior surface of the holder sidewall.
